(19) United States
(12) Patent Application Publication
(10) Pub. No.: US 2020/0127153 A1
(43) Pub. Date: Apr. 23, 2020

(54) WIRE INTERCONNECTION FOR SOLAR CELLS

(71) Applicant: Massachusetts Institute of Technology, Cambridge, MA (US)

(72) Inventors: Emanuel Sachs, Newton, MA (US); Tonio Buonassisi, Cambridge, MA (US); Luke Thomas Meyer, Rock City, IL (US)

(73) Assignee: Massachusetts Institute of Technology, Cambridge, MA (US)

(21) Appl. No.: 16/624,845

(22) PCT Filed: Jun. 26, 2018
(86) PCT No.: PCT/US2018/039437

§ 371 Date: Dec. 19, 2019

Related U.S. Application Data
(60) Provisional application No. 62/628,893, filed on Feb. 9, 2018.
(60) Provisional application No. 62/524,809, filed on Jun. 26, 2017.

(51) Int. Cl. H01L 31/05; H01L 31/068

(52) U.S. Cl. CPC H01L 31/0508; H01L 31/0684

(57) ABSTRACT

Embodiments related to solar modules and their manufacture are disclosed. In one embodiment, a solar module may include first and second solar cells with first and second interconnection wires disposed on upper and lower surfaces of one and/or both of the solar cells, and a cross-connect wire disposed between the solar cells and electrically connected to the first and second interconnection wires. A portion of each of the first and second interconnection wires may be removed to electrically isolate the upper surfaces from the lower surfaces of each solar cell while retaining an electrical connection between the upper surface of one cell with the lower surface of the adjoining solar cell through the cross-connect wire. In some embodiments, the first and second interconnection wires may be arranged as a plurality of offset wires located on opposing sides of the solar cells which may reduce stresses applied to the solar cells.

### CROSS-REFERENCE TO RELATED APPLICATIONS

This application is a national stage filing under 35 U.S.C. § 371 of International Patent Application No. PCT/US2018/039437, filed Jun. 26, 2018, which claims the benefit under 35 U.S.C. § 119(e) to U.S. Provisional Application No. 62/524,809, filed Jun. 26, 2017, and also claims the benefit under 35 U.S.C. § 119(e) to U.S. Provisional Application No. 62/628,893, filed Feb. 9, 2018, which are herein incorporated by reference in their entirety.

### GOVERNMENT LICENSE RIGHTS

This invention was made with Government support under Grant No. DE-EE0007535 awarded by the Department of Energy. The Government has certain rights in the invention.

### FIELD

Disclosed embodiments are related to wire interconnections for solar cells.

### BACKGROUND

Traditionally, solar cells are interconnected with wires extending between electrical contacts on opposite sides of the cells. To mitigate the strain within each solar cell, conventional buswires utilize multiwire technologies which include the use of 10 to 20 thin round wires for the solar cell interconnection. Multiwires have shown promising results such as smaller solar cell stresses, reduced sensitivity to solar cell cracking, reduced silver paste usage, and higher efficiencies through higher current and fill factors.

### SUMMARY

In some embodiments, a solar cell module includes a first solar cell and a second solar cell, where the first solar cell and the second solar cell both include an upper surface, a lower surface opposing the upper surface, at least one electrical contact located on the upper surface, and at least one electrical contact located on the lower surface. The solar cell module also includes at least one first interconnection wire that is disposed on and extends across at least a portion of the upper surface of the first solar cell, at least one second interconnection wire that is disposed on and extends across at least a portion of the lower surface of the second solar cell, and at least one cross-connect wire disposed between the first solar cell and the second solar cell. The at least one first interconnection wire is in electrical contact with the at least one electrical contact on the upper surface of the first solar cell and the at least one second interconnection wire is in electrical contact with the at least one electrical contact on the lower surface of the second solar cell. The at least one cross-connect wire is in electrical contact with the at least one first interconnection wire and the at least one second interconnection wire.

In some embodiments, a method for interconnecting solar cells includes positioning a first solar cell proximate to a second solar cell, where the first solar cell and the second solar cell both include an upper surface, a lower surface opposing the upper surface, at least one electrical contact located on the upper surface, and at least one electrical contact located on the lower surface. The method also includes electrically connecting at least one first interconnection wire to the at least one electrical contact on the upper surface of both the first solar cell and second solar cell, electrically connecting at least one second interconnection wire to the at least one electrical contact on the lower surface of both the first solar cell and second solar cell, and electrically connecting a cross-connect wire to the at least one first interconnection wire and the at least one second interconnection wire, wherein the cross-connect wire is disposed between the first solar cell and the second solar cell.

In some embodiments, a solar cell module includes a first solar cell and a second solar cell, wherein the first solar cell and the second solar cell both include an upper surface, a lower surface opposing the upper surface, at least one electrical contact located on the upper surface, and at least one electrical contact located on the lower surface. The solar cell module also includes at least one first interconnection wire that is disposed on and extends across at least a portion of the upper surface of both the first solar cell and the second solar cell, at least one second interconnection wire that is disposed on and extends across at least a portion of the lower surface of both the first solar cell and the second solar cell, and at least one cross-connect wire disposed between the first solar cell and the second solar cell. The at least one first interconnection wire is in electrical contact with the at least one electrical contact on the upper surface of both the first solar cell and the second solar cell and the at least one second interconnection wire is in electrical contact with the at least one electrical contact on the lower surface of both the first solar cell and the second solar cell. The at least one cross-connect wire is in electrical contact with the at least one first interconnection wire and the at least one second interconnection wire.

In some embodiments, a mechanical wire cutter includes a first outer blade, a second outer blade, and an inner blade slidably disposed between the first outer blade and the second outer blade. The inner blade includes an indentation sized and shaped to receive a wire when the inner blade is in a first extended position with the indentation extended beyond the first outer blade and the second outer blade. The wire is cut by the first outer blade and the second outer blade when the inner blade is moved from the first extended position to a second retracted position with the indentation located between the first outer blade and the second outer blade.

In some embodiments, a method for cutting an interconnection wire of a solar cell includes moving an inner blade slidably disposed between a first outer blade and a second outer blade to a first extended position, moving the inner blade from a first lateral position to a second lateral position to capture a wire in an indentation formed in the inner blade, and moving the inner blade to a second retracted position with the indentation located between the first outer blade and the second outer blade to cut the captured wire with the first outer blade and the second outer blade.

It should be appreciated that the foregoing concepts, and additional concepts discussed below, may be arranged in any suitable combination, as the present disclosure is not limited in this respect. Further, other advantages and novel features of the present disclosure will become apparent from the following detailed description of various non-limiting embodiments when considered in conjunction with the accompanying figures.

### BRIEF DESCRIPTION OF DRAWINGS

The accompanying drawings are not intended to be drawn to scale. In the drawings, each identical or nearly identical component that is illustrated in various figures may be represented by a like numeral. For purposes of clarity, not every component may be labeled in every drawing. In the drawings:

FIGS. 1A-1F depict one embodiment of an interconnection process for solar cells;

FIG. 2 is a block diagram of one embodiment of an interconnection process for solar cells;

FIG. 3 depicts one embodiment of a mechanical wire cutter;

FIGS. 4A-4D depict one embodiment of a cutting process for interconnection wires;

FIG. 5 is a block diagram of one embodiment of a wire cutting process;

FIG. 6 depicts another embodiment of a mechanical wire cutter;

FIG. 7 depicts one embodiment of a mechanical wire cutter array in a first position;

FIG. 8 depicts the mechanical wire cutter array of FIG. 7 in a second position;

FIG. 9 depicts yet another embodiment of a mechanical wire cutter array;

FIGS. 10A-10B depict another embodiment of an interconnection process for solar cells;

FIGS. 11A-11B depict yet another embodiment of an interconnection process for solar cells;

FIG. 12 depicts one embodiment of an assembly of solar cells including a solar cell interconnection;

FIGS. 13A-13E depict an embodiment of a solar cell interconnection;

FIGS. 14A-14E depict a conventional solar cell interconnection;

FIGS. 15A-15B depict an embodiment of a solar cell interconnection model;

FIGS. 16A-16C depict finite element analysis results for the solar cell interconnection model of FIGS. 15A-15B;

FIG. 17 depicts finite element analysis results for a conventional solar cell interconnection;

FIG. 18 depicts finite element analysis results for an embodiment of a solar cell interconnection;

FIGS. 19A-19B depict yet another embodiment of a solar cell interconnection model;

FIG. 20 depicts an embodiment of an encapsulated solar cell interconnection;

FIGS. 21A-21C depict finite element analysis results for the solar cell interconnection model of FIGS. 20A-20B;

FIGS. 22A-22C depict a finite element analysis results comparison between the embodiments of a solar cell interconnection model shown in FIGS. 15A-15B and FIGS. 19A-19B;

FIG. 23 depicts finite element analysis results for a conventional encapsulated solar cell interconnection;

FIG. 24 depicts finite element analysis results for an embodiment of an encapsulated solar cell interconnection;

FIG. 25 depicts an embodiment for a testing assembly;

FIGS. 26A-26C depict an embodiment of testing failure modes for a solar cell interconnection;

FIG. 27 depicts exemplary failure testing data for embodiments of a solar cell interconnection; and

FIGS. 28A-28C depict microscopic views of an embodiment of a solar cell interconnection failure.

### DETAILED DESCRIPTION

Despite the benefits of multiwire technology, the implementation of multiwires in solar cells remains complex due to the inclusion of additional manufacturing steps. These manufacturing steps may include laminating wires into sheets to obtain acceptable alignment or the use of expensive equipment to snake the wires between cells. These complex steps are used due in part to the conventional buswire tabbing (i.e., stringing) method of snaking buswires between positive and negative contact areas (e.g., fingers, sheets, and strips) which forms an “S”-style interconnection. Another challenge with the “S”-style interconnection includes mitigating the effect of stresses this configuration imparts onto adjacent cell side surfaces during thermal cycling, which may increase cell breakage and negatively affect cell yield. For example, during solar panel operation, several degradation and failure modes are associated with the fluctuation of operating temperature. For example, the operating temperatures of a system may reach extremes between −40° C. and 85° C. which causes corresponding expansions and contractions of the many different materials within the solar panel. Due to mismatched coefficients of thermal expansion between silicon, solder, wire, encapsulant, glass superstrate, other glass, and/or any other cell materials, these temperature changes can also cause the cells, and therefore the gap between the cells (i.e., side surface to side surface cell spacing), to change during thermal cycling as well which causes thermal cycling of the associated interconnections. As a result, typical solar cell assemblies including multiwire connections may have relatively large spacings between adjacent solar cells to accommodate these spacing changes between cells during usage.

In view of the above, the inventors have recognized the numerous benefits of a solar cell interconnection that replaces “S”-style wires with a cross-connect wire disposed between adjacent solar cells that is electrically connected to one or more interconnection wires located on the corresponding faces of the solar cells. Such an arrangement avoids the snaking of wires between positive and negative contact areas of adjacent solar cells which has numerous benefits. The interconnection may simplify tabbing (i.e., stringing) equipment used to assembly solar cell modules, mitigate stresses encountered by the interconnect or cell caused by external factors, allow for suitable interconnection wire alignment and multiplicity without the use of a wire carrier, provide wire strain relief for cell spacing changes due to thermal cycling or mechanical cycling, allow denser arrangement of solar cells (i.e., closer cell spacing), and/or allow the use of optimized and different interconnection wire or cross-connect wire cross sections and coatings for minimal shading losses and improved electrical and mechanical contacts.

In view of the above, in one embodiment of the present disclosure, a method for interconnecting solar cells includes positioning a first solar cell proximate to a second solar cell. Each of the solar cells includes an upper surface, a lower surface opposite the upper surface, and at least one side surface extending between the upper and lower surfaces. A first interconnection wire is positioned on and extends across at least a portion of the upper surfaces of the first and second solar cells. The first interconnection wire is then electrically connected to at least one electrical contact disposed on the upper surface of the first solar cell and at least one electrical contact disposed on the upper surface of the second solar cell. A second interconnection wire is positioned across at least a portion of the lower surfaces of the first and second solar cells. The second interconnection wire is then electrically connected to at least one electrical contact disposed on the lower surface of the first solar cell and at least one electrical contact disposed on the lower surface of the second solar cell. A cross-connect wire is positioned between the first and second solar cells and electrically connected to the first interconnection wire and second interconnection wire at a location between the first and second solar cells. A portion of the first interconnection wire is removed such that the electrical contacts positioned on the upper surfaces of the first and second solar cells are electrically isolated from each other. Similarly, a portion of the second interconnection wire is removed such that the electrical contacts positioned on the lower surfaces of the first and second solar cells are electrically isolated from each other. Instead, the at least one electrical contact on the upper surface of the first solar cell may be electrically connected to the at least one electrical contact located on the lower surface of the second solar cell through the cross-connect wire placing the solar cells in series with one another. Thus, the solar cells may be interconnected to form a solar cell module without snaking or bending “S”-style interconnection wires between the adjacent solar cells.

In some embodiments, the amount of wire removed from a first interconnection wire and/or a second interconnection wire may be sufficient to prevent electrical shorting due to disturbances of the ends of the wire as might occur in the case of thermal expansion and/or other forces being applied to the interconnected solar cells. A portion of wire from a first interconnection wire and/or a second interconnection wire may be removed using any suitable arrangement including, but not limited to, mechanical cutters and laser cutters. In some embodiments, the amount of wire removed may be approximately equal to a diameter of an interconnection wire. In some embodiments, an amount of interconnection wire removed may be greater than or equal to approximately 75 μm, 100 μm, 150 μm, 200 μm, 250 μm, 300 μm, 350 μm, or any other suitable length. Correspondingly, an amount of interconnection wire removed may be less than or approximately equal to 400 μm, 325 μm, 275 μm, 225 μm, 175 μm, 125 μm, 90 μm, or any other suitable length. Combinations of the above noted ranges are contemplated including, for example, an amount of interconnection wire removed may be between or equal to 75 μm 125 μm, 100 μm 225 μm, 100 μm and 400 μm, as well as 75 μm 325 μm. Of course, any suitable amount of interconnection wire may be removed, including amounts both greater than and less than those noted above, as the present disclosure is not so limited.

In some embodiments, the amount of wire removed from a first interconnection wire and/or a second interconnection wire may be greater than 0.25 wire diameters, 0.5 wire diameters, 0.75 wire diameters, 1 wire diameter, 1.5 wire diameters, or any other suitable diameter. Correspondingly, an amount of interconnection wire removed may be less than 2 wire diameters, 1.25 wire diameters, 1 wire diameter, 0.75 wire diameters, 0.5 wire diameters, or any other suitable diameter. Combinations of the above noted ranges are contemplated including, for example, an amount of interconnection wire removed may be between or equal to 0.25 wire diameters and 1.5 wire diameters, 0.5 wire diameters and 1.25 wire diameters, as well as 0.25 wire diameters. Of course, any suitable amount of wire may be removed from the first interconnection wire and the second interconnection wire, including amounts both greater than and less than those noted above, as the present disclosure is not so limited.

While the above embodiment is directed to forming a series connection between two solar cells, embodiments in which the disclosed methods and systems may be modified to create modules with a plurality of solar cells that are connected in series and/or parallel with one another using an arrangement of a plurality of interconnection and a corresponding plurality of cross-connect wires are also contemplated as the present disclosure is not so limited.

In some embodiments, during an intermediate step, a solar cell module may include a first solar cell and a second solar cell. The first and second solar cells may include an upper surface, a lower surface opposite the upper surface, and at least one side surface extending between the upper surface and lower surface. The solar cell module may also include a first interconnection wire that is disposed on and extends across at least a portion of the upper surfaces of the first and second solar cells. The first interconnection wire may be electrically connected to at least one electrical contact disposed on the upper surface of the first solar cell and at least one electrical contact disposed on the upper surface of the second solar cell. The solar module may also include a second interconnection wire that is disposed on and extends across at least a portion of the lower surfaces of the first and second solar cells. The second interconnection wire may be electrically connected to at least one electrical contact disposed on the lower surface of the first solar cell and at least one electrical contact disposed on the lower surface of the second solar cell. The first interconnection wire and second interconnection wire may be electrically connected to a cross-connect wire disposed between the first solar cell and the second solar cell such that the first and second interconnection wires are electrically connected to one another through the cross-connect wire. This intermediate assembly may then be subjected to additional processing and manufacturing steps to provide the desired interconnected module.

In some embodiments, a solar cell module includes a plurality of first interconnection wires disposed on and extending across the upper surfaces of a corresponding plurality of solar cells and a plurality of second interconnection wires disposed on and extending across the lower surfaces of the plurality of solar cells. The upper surface and lower surface interconnection wires may also be independently connected to the corresponding electrical contacts formed on the upper and lower surfaces of the solar cells. At least one cross-connect wire may be electrically connected with the plurality of first and second interconnection wires such that the solar cells are interconnected with one another according to the methods and arrangements noted above. Thus, in one embodiment, the cross-connect wire may electrically connect the plurality of first interconnection wires to the plurality of second interconnection wires. In certain embodiments, the plurality of first interconnection wires may be offset from the plurality of second interconnection wires so that they are not aligned in the same planes oriented normal to the opposing top and bottom surfaces of the solar cells. According to this embodiment, the plurality of first interconnection wires and the plurality of second interconnection wires may be substantially parallel to each other such that they extend in a first direction and are offset from each other in a direction that is perpendicular to that first direction. In other words, the planes normal to the opposing top and bottom surfaces of the solar cells the interconnection wires are located within may be offset from one another. Further, the plurality of first interconnection wires and the plurality of second interconnection wires may contact the cross-connect wire at different locations along the length of a cross-connect wire that extends between adjacent solar cells.

Without wishing to be bound by theory, and as elaborated on below, it is believed that offsetting the first and second sets of interconnection wires from one another may reduce the resulting stresses in an electrical connection by providing strain relief and/or an increased ability of the interconnection wires to buckle during cyclic changes in solar cell spacing occur as might occur during thermal cycling. In some embodiments, the plurality of first and second interconnection wires may be offset regularly, in a repeating pattern. However, embodiments in which the spacing of the first and second interconnection wires is irregular are also contemplated. Further, in some embodiments, interconnection wires located on one side of a solar cell or module may be located within some predetermined distance of a midpoint between the corresponding interconnection wires located on the opposing side of the solar cell or module. For example, an interconnection wire may be located within a distance from the midpoint of the two opposing interconnection wires that is between or equal to 0% and 25% of the overall distance between the two interconnection wires. Thus, an interconnection wire may be located in a number of different positions between two interconnection wires located on an opposing side of a solar cell or module. In one specific example, an interconnection wire may be located at the midpoint between the two interconnection wires located on the opposing side of the solar cell or module. However, it should be understood that the current disclosure is not limited to any particular pattern and/or spacing of the interconnection wires relative to each other.

In some embodiments, a mechanical wire cutter for cutting wire may include a first outer blade, a second outer blade, and an inner blade. The inner blade may be slidably disposed between the first outer blade and the second outer blade in at least one direction relative to the first outer blade in the second outer blade. The inner blade may include an indentation sized and shaped to receive a wire. In particular, the indentation may be sized and shaped to receive, hold, and apply force to an interconnection wire. The indentation may be arranged to accommodate a wire oriented in a direction that is angled and/or substantially perpendicular relative to the first outer blade and the second outer blade. For example, the indentation may be extend through the inner blade in a direction that is angled, and in some embodiments substantially perpendicular, to an interface of the inner blade with the first and/or second outer blade. The inner blade may be moveable between a first extended position and a second retracted position. In a first extended position, the indentation is positioned distally outward from an associated edge of the first outer blade and the second outer blade. In the first extended position, the indentation may also receive a wire to be cut by the wire cutter. After a wire is received in the indentation, the inner blade may be moved to the second retracted position where the indentation is located between the first outer blade and the second outer blade. Accordingly, a portion of wire held within the indentation may be cut by the first outer blade and the second outer blade as the inner blade is moved toward the second retracted position. Thus, the wire may be cut at two opposing ends of the portion of the wire held within the indentation with the ends of the cut portion corresponding to the locations of the interfaces of the inner blade with the first and second outer blades. Additionally, such an arrangement may beneficially allow a portion of the wire to be removed without significantly stressing the remaining portions of the wire.

In some embodiments, a mechanical wire cutter includes one or more actuators arranged to selectively translate the first outer blade, second outer blade, and/or inner blade relative to one another. This relative translation of the blades may be done either independently or through a combination of movements of the various blades. For example, the wire cutter may include a first actuator operatively coupled to the first outer blade and the second outer blade such that the actuator is constructed and arranged to move the first and second outer blades relative to a stationary inner blade. Alternatively, a first actuator may be operatively coupled to the inner blade of a mechanical wire cutter such that the actuator is constructed and arranged to move the inner blade relative to stationary first and second outer blades. The first actuator may be any suitable actuator including, but not limited to, an electric motor drive linear actuator, an electrical solenoid actuator, a linear hydraulic actuator, a linear pneumatic actuator, and/or any other appropriate type of actuator capable of providing relative motion in a desired direction between the inner and outer blades of a mechanical wire cutter. While embodiments in which one of the inner or outer blades is movable are described above, embodiments in which both the inner and outer blades of a wire cutter are displaced during an actuation cycle are also contemplated. Additionally, in some embodiments, it may be desirable to translate a mechanical wire cutter between two or more positions for cutting wires at these separate positions. For example, a wire cutter may also include one or more second actuators connected to a chassis of the wire cutter which may be arranged to translate the wire cutter in one or more directions between the two or more positions.

In some embodiments, a method of cutting an interconnection wire includes moving an inner blade disposed between a first outer blade and a second outer blade to a first extended position so that an indentation formed in the inner blade is extended beyond the distal edges of the first and second outer blades. The inner blade may be moved from a first lateral position to a second lateral position to capture a wire inside of the indentation. The indentation may be sized and shaped to appropriately capture and hold a wire therein. In combination with the first and second outer blades, the indentation may also be constructed to apply a force to the wire when the inner blade is retracted relative to the outer blades to cut and remove a portion of the wire. Specifically, the inner blade may be moved from the first extended position to a second retracted position to move the indentation between the first outer blade and the second outer blade to shear the captured wire against the outer edges of the first and second outer blades. In some embodiments, the captured wire may be cut simultaneously by the first and second outer blades to prevent excess stress on the wire.

In some embodiments, it may be desirable for a wire cutter to be positioned closely or in contact with a wire to be cut. That is, cutting blades such as a first outer blade and a second outer blade may be placed in contact with the wire to be cut prior to the actual cutting of the wire. Such an arrangement may reduce the amount of deformation and stress added to the wire during a cutting process. In some embodiments, a wire cutter may include a contact sensor arranged to determine the position of the first and second outer blades relative to a wire. The contact sensor may include a voltage generator which applies a non-zero voltage across the first and second outer blades. According to this embodiment, when the first and second outer blades are placed into contact with a conductive wire, a circuit will be completed between the first and second outer blades which may cause a detectable decrease in voltage and/or a flow of current between the first and second outer blades using an appropriate voltage and/or current sensor. Such a voltage decrease and/or flow of current may be indicative of contact of the first and second outer blades with the wire to be cut. In an alternative embodiment, the contact sensor may include an optical sensor which may receive optical information from the wire cutter and/or wire to be cut so that the relative position of the inner and outer blades relative to a wire to be cut may be determined. Such an arrangement may be useful for feedback control of the various blades of the wire cutter. While two possible contact sensing arrangements are described above, it should be understood that the current disclosure is not limited to only these embodiments. Instead, any appropriate method and/or system capable of detecting contact and/or the close proximity of the one or more outer blades of a mechanical wire cutter to a wire to be cut may be used as the disclosure is not limited in this fashion.

In some embodiments, a plurality of wire cutters may be arranged in an array so that multiple wires at regular or irregularly spaced intervals may be cut simultaneously. According to this embodiment, the wires to be cut may be parallel to one another so that multiple wire cutters may be rigidly mounted to one another and operated simultaneously to remove portions of one or more associated wires. In one embodiment, the wire cutters may be linearly arranged such that an outer blade of a first wire cutter may be adjacent to an outer blade of a second wire cutter. However, embodiments in which one or more intervening structures are included and/or the mechanical wire cutters are spaced from one another are also contemplated. According to this embodiment, indentations on an inner blade of each of the wire cutters may be parallel to one another with openings facing in the same direction. In some embodiments, multiple wire cutter arrays may be used to remove portions of wire attached to different regions of the solar cell simultaneously. For example, multiple arrays of wire cutters may be used to remove portions of interconnection wire disposed on and extending across both the upper surface of a solar cell and a lower surface of the solar cell. In this example, the arrays of wire cutters may be disposed opposite one another so that one array may remove portions of wire from the upper surface of the solar cell and a second array may remove portions of wire from the lower surface of the solar cell. Of course, it should be understood that one or more arrays of wire cutters may be positioned in any suitable location relative to a first and second solar cell to effectively remove portions of interconnection wire as the present disclosure is not so limited.

For the sake of clarity, the embodiments described below are discussed relative to interconnection wires positioned on the upper surfaces and lower surfaces of the related solar cells. However, it should be understood that the described surfaces may be generalized to any appropriate upper and lower surfaces and are not limited to any particular orientation. Therefore, in certain embodiments, an upper surface of a solar cell may correspond to the sunny side (i.e., photovoltaic side) of a solar cell and a lower surface of the solar cell may correspond to the back side (i.e., non-photovoltaic side) of a solar cell. In other embodiments, an upper surface of a solar cell may correspond to the back side and a lower surface of the solar cell may correspond to the sunny side. Of course, the upper and lower sides of the solar cell may be any suitable combination of opposing surfaces of a solar cell that allow for interconnection of one or more electrical contacts of adjacent solar cells as the present disclosure is not so limited.

Various embodiments of the present application may include solar cell interconnection constructions and methods for manufacturing those interconnections. More specifically, in one embodiment, the disclosed interconnections may avoid snaking interconnection wires from the back side of a first solar cell to the sunny side of a second solar cell by using two independent sets of interconnection wire and a cross-connect wire. A first set of interconnection wires are attached to the lower surface of the first solar cell while another set of interconnection wires are attached to the upper surface of the second solar cell. A cross-connect wire may be inserted in between and perpendicular to these two sets of interconnection wires. Electrical contact may be made between the interconnection wires and solar cells and between the interconnection wires and cross-connect (i.e., interconnection) wire using any suitable technique, including, but not limited to, soldering, applying conductive adhesives, and welding (e.g., spot welding). At this stage, the cells are shorted. Removal of small portions of the upper surface interconnection wires and lower surface interconnection wires may be done to create an electrical pathway from the negative contact area on the first solar cell to the positive contact area on the second solar cell, thereby completing the cell interconnection. For example, a portion of each of the first and second interconnection wires may be removed to electrically isolate the upper surfaces from the lower surfaces of each solar cell while retaining an electrical connection between the upper surface of one cell with the lower surface of the adjoining solar cell through the cross-connect wire. Using the proposed method of cell interconnection, interconnection wire technologies are suitable for use with any thin or free-standing cells with thicknesses in the range of about 50 μm to 200 μm. The proposed interconnection technique may replace traditional interconnection wire “S”-style interconnects so that the interconnection of solar cells may be simplified and resistance to thermal cycling of the solar cell may also be improved.

Without wishing to be bound by theory, a minimum cell spacing with the disclosed interconnect systems and methods disclosed herein may be determined by a transverse dimension (e.g., a diameter) of the cross-connect wire and the ability to remove small portions of interconnection wire on either side of the cross-connect wire to provide the desired electrical interconnection. Thus, a spacing of the adjacent solar panels may be between or equal to, 2 and 10 times, 2 and 5 times, and/or any other appropriate multiple of a transverse dimension of the cross-connect wire, though other spacing are also contemplated as the disclosure is not so limited. In a related embodiment, a thickness of the cross-connect wire may be less than or equal to 3 times a thickness of the solar cells. In either case, the cell spacing may be reduced in comparison to typical systems, thereby improving solar cell density within a solar module.

In some embodiments, appropriate solar cell spacing for use with a cross-connect wire and interconnection wires may be greater than or equal to approximately 0.3 mm, 0.5 mm, 1 mm, 1.5 mm, 2 mm, 2.5 mm, 3 mm, or any other suitable spacing. Correspondingly, a solar cell spacing may be less than or equal to approximately 3.5 mm, 3 mm, 2.5 mm, 2 mm, 1.5 mm, 1 mm, 0.5 mm, or any other suitable spacing. Combinations of the above noted ranges are contemplated including, for example, solar cell spacing between or equal to 0.3 mm and 1.5 mm, 0.5 mm and 2 mm, 1 mm and 3 mm, as well as 0.5 mm 2.5 mm. Of course, any suitable cell spacing for a given interconnection wire thickness and corresponding wire removal lengths may be used including spacing both greater than and less than those noted above as the present disclosure is not so limited.

In some embodiments, appropriate solar cell thicknesses for use with a cross-connect wire and interconnection wires may be greater than or equal to approximately 50 μm, 75 μm, 100 μm, 150 μm, 250 μm, 350 μm, 450 μm, 500 μm, or any other suitable thickness. Correspondingly, a solar cell thickness may be less than or equal to approximately 550 μm, 475 μm, 375 μm, 275 μm, 175 μm, 125 μm, 100 μm, or any other suitable thickness. Combinations of the above noted ranges are contemplated including, for example, solar cell thickness between or equal to 75 μm and 275 μm, 100 μm and 475 μm, 150 μm and 475 μm, as well as 50 μm and 550 μm. Of course, any suitable cell thickness may be used including thicknesses both greater than and less than those noted above as the present disclosure is not so limited.

In some embodiments, it may be desirable for a cross-connect wire to have a diameter, or any other appropriate transverse dimension, corresponding to an associated solar cell thickness. For example, the cross-connect wire may have a diameter approximately equal to that of the solar cell thickness so that interconnection wires disposed on and extending across an upper surface and a lower surface of a solar cell can remain substantially straight and not deformed. However, in other embodiments, it may be desirable for the cross-connect wire to have a diameter larger than that of a solar cell thickness so that the cross-connect wire may reduce the amount of electrical resistance between interconnected solar cells. In some embodiments a cross-connect wire may have a diameter greater than or equal to approximately 0.5 times a solar cell thickness, 1 times solar a cell thickness, 1.25 times a solar cell thickness, 1.5 times a solar cell thickness, 2 times a solar cell thickness, or any other suitable. Correspondingly, a cross-connect wire may have a diameter less than or equal to approximately 5 times a solar cell thickness, 3 times a solar cell thickness, 2 times a solar cell thickness, 1.5 times a solar cell thickness, 1.25 times a solar cell thickness, 1 times a solar cell thickness, or any other suitable multiple of an associated solar cell thickness. Combinations of the above noted ranges are contemplated including, for example, cross-connect wire diameters between or equal to 0.5 and 5 times a solar cell thickness, 0.5 and 2 times a solar cell thickness, 1 and 1.5 times a solar cell thickness, 1 and 3 times a solar cell thickness, as well as 0.5 and 1.5 times a solar cell thickness. Of course, any suitable diameter may be used for the cross-connect wire, including amounts both greater than and less than those noted above as the present disclosure is not so limited.

In some embodiments, it may be desirable for a vertical height change between a cross-connect wire and an adjacent electrical contact disposed on a surface of an associated solar cell to correspond to the associated solar cell thickness. Without wishing to be bound by theory, an interconnection wire may remain straight and substantially unreformed due to a small or zero change in vertical height between a connection with the cross-connect wire and adjacent electrical contacts of an associated solar cell. Accordingly, in some embodiments, a change in the vertical height between the cross-connect wire and the adjacent electrical contacts of the solar cells may be greater than or equal to approximately 0.5 times a solar cell thickness, 0.75 times a solar cell thickness, 1 times a solar cell thickness, 1.25 times a solar cell thickness, or any other suitable multiple of an associated solar cell thickness. Correspondingly, a change in vertical height between the cross-connect wire and the adjacent electrical contacts of the solar cells may be less than or equal to approximately 1.5 times a solar cell thickness, 1.25 times a solar cell thickness, 1 times a solar cell thickness, 0.75 times a solar cell thickness, or any other suitable multiple of an associated solar cell thickness. Combinations of the above noted ranges are contemplated including, for example, vertical height changes between or equal to 0.5 and 1.25 times solar cell thickness, 1 and 1.25 times solar cell thickness, 0.5 and 0.75 times solar cell thickness, as well as 0.75 and 1.25 times solar cell thickness. Of course, any suitable vertical height change between the cross-connect wire and adjacent electrical contacts may be employed, including amounts both greater than and less than those noted above, as the present disclosure is not so limited.

The length of unsupported interconnection wire on either side of the cross-connect wire may be approximately equal to the distance from the cross-connect to the electrical connection at the electrical contact on an associate solar cell. For example, there may be approximately 1.4 mm of unsupported interconnection wire when there is an approximately 1 mm cell gap, approximately 1 mm cell side surface to cross-connect wire electrical connection, and a 100 μm cross-connect wire radius. Without wishing to be bound by theory, if the cells have only one degree of freedom, cell displacements may have one of two effects: the sunny side or back side interconnection wires may buckle or the cross-connect wire may be bent (i.e., deformed). Without wishing to be bound by theory, the larger the unsupported length of interconnection wire the more deflection the interconnection wire may undergo for a given force applied to the interconnection wire. Accordingly, it may be desirable to minimize the unsupported length of wire for a given cell spacing and electrical contact position. In some embodiments, the amount of unsupported interconnection wire may be greater than or approximately equal to 0.75 mm, 1 mm, 1.5 mm, 2 mm, 2.5 mm, and or any other suitable length. Correspondingly, the amount of unsupported interconnection wire may be less than or approximately equal to 3 mm, 2.25 mm, 1.75 mm, 1.25 mm, 0.8 mm, and/or any other suitable length. Combinations of the above noted ranges are contemplated including unsupported links of wire between 1 mm and 2.5 mm, 1 mm and 3 mm, 2 mm and 2.5 mm, as well as 0.75 and 3 mm. Of course, any suitable length of unsupported wire may be employed including links greater than and less than those noted above, as the present disclosure is not so limited.

In some embodiments, an interconnection wire and/or a cross-connect wire may have a particular cross-section to improve solar cell efficiency. Without wishing to be bound by theory, light may reflect off of the interconnection wires and/or cross-connect wires. When a solar cell is covered in encapsulant and/or a glass layer, the solar cell may exhibit a critical angle for total internal reflection of light at an interface between the exterior glass layer and the air in the surrounding ambient environment. Accordingly, in some embodiments, it may be desirable to control an angle of light reflected from the interconnection wires and/or cross-connect wires to reflect light at an angle that is less than this critical angle. For example, unlike a circular cross section which may reflect light in a number of different directions, in some embodiments, an interconnection wire and/or a cross-connect wire may have a polygonal cross-section such as a triangle or pentagon which may include top surfaces oriented outward from an underlying surface of a solar cell such that incident light on these surfaces may be reflected off of the surfaces at a desired angle. According to this embodiment, these surfaces of the cross-connect wire may be angled by a predetermined amount relative to an upper or lower surface of solar cell such that incident light may either be reflected towards a photosensitive surface of the solar cells and/or at a shallow angle that is less than the critical angle to promote total internal reflection of the incident light. In some embodiments, polygonal cross-sections may be combined with rounded cross-sections in order to provide additional total internal reflection of light. For example, an approximately triangular cross section may include rounded or semicircular edges adjacent a surface of a solar cell the wire is disposed on. As another example, an approximately pentagonal cross section may have a pointed top and rounded sides. To further promote total internal reflection of the reflected light, in some embodiments, an encapsulant of a system may be optically matched an associated glass layer such that an index of refraction of the encapsulated is substantially the same as a corresponding index of refraction of the glass layer to further promote the reflection of light rays back into the photovoltaic.

Depending on the particular embodiment, an interconnection wire and/or a cross-connect wire may include one or more flat surfaces that are angled relative to an underlying surface a solar cell in order to promote total internal reflection of incident light within the a solar module. For example, as noted above, the one or more flat angled surfaces may be angled to a suitable angle so as to cause light to reflect at a shallow angle to cause total internal reflection. In some embodiments, the angle of the flat angled surface relative to an upper or lower surface of a solar cell may be greater than or equal to approximately 20°, 22°, 25°, 28°, 30°, 35°, and/or any other suitable angle. Correspondingly, the angle of the flat angled surface relative to the solar cell may be less than or equal to approximately 40°, 32°, 29°, 27°, 24°, 21°, and/or any other suitable angle. Combinations of the above noted ranges are contemplated including, for example, angles between 20° and 40°, 22° and 32°, 22° and 27°, as well as 25° and 32°. Of course, any suitable angle may be used including angles greater than and less than those noted above as the present disclosure is not so limited.

Conventional solar cells include a wide variety of materials and structural arrangements. For example, typical solar cells may be covered in an encapsulant with a glass superstrate layer on the upper or sunny surface of the solar cells and an opaque layer on the lower or dark surface of the solar cells. In such an embodiment, the solar cells may include electrical contacts in the form of a plurality of relatively thin conductive fingers on the upper surfaces of the solar cells and conductive sheets on the bottom surfaces of the solar cells. In another embodiment, the one or more solar cells may be bifacial solar cells. In such an embodiment, interconnected bifacial solar cells may be placed in an encapsulant between two opposing glass layers associated with the upper and lower surfaces of the solar cells. Such an arrangement may permit the solar cells to absorb light incident on either side of the solar cell assembly. In such an embodiment, the electrical contacts on both the top and bottom surfaces of the cells may include a plurality of conductive fingers.

For the sake of clarity, the current embodiments described in the application describe electrical connections between the various electrical contacts and/or fingers of the solar cells. However, it should be understood that the current disclosure is not limited to connection with any particular type of electrical contact of a solar cell. Suitable electrical contacts for use with a solar cell may include conductive fingers, strips, solid sheets, combinations of the forgoing, and/or any other appropriate form or electrical contact suitable for use with a solar cell. Therefore, it should be understood that any suitable type and number of electrical contacts may be used on a solar cell.

In some embodiments, a solar cell may be arranged with a particular number of electrical contacts to which interconnection wires may be connected. For example, in some embodiments, an upper surface of a solar cell may include a plurality of fingers or other electrical contacts which may be interconnected using an interconnection wire. The plurality of fingers may be disposed at regular or irregular intervals in a pattern. On the lower surface of a solar cell, the solar cell may include a single electrical sheet contact (i.e. a conductive sheet), or a plurality of fingers or metal strips which may be disposed at regular or irregular intervals. In some embodiments, an equal number of interconnection wires may be used on each of the upper and lower surfaces of a solar cell to electrically connect electrical contact(s) on the upper surface and electrical contact(s) on the lower surface. In some embodiments, a different number of interconnection wires may be used on each of the upper surface and the lower surface of a solar cell. For example, 15 interconnection wires may be used to electrically connect electrical contact(s) on the upper surface and 14 interconnection wires may be used to electrically connect electrical contact(s) on the lower surface of a solar cell. Of course, any suitable number of contacts may be used on each of the upper surface and the lower surface of the solar cell along with any suitable number of interconnection wires.

The interconnection and cross-connect wires described herein may have any appropriate construction suitable for use in electrically connecting the electrical contacts of two or more solar cells. For example, appropriate wires may include, but are not limited to braided wires, solid wires, stranded wires, and/or any other appropriate form of wire. In some embodiments, a wire may also be formed of a plurality of smaller wires. For example, a wire may include 10 to 20 smaller wires though any other appropriate number of smaller wires may be used as well. Such an arrangement may help to reduce the physical strain on any one wire. Additionally, while the use of wires may be advantageous due to their flexibility and ease of use during manufacture, the current disclosure is not limited in this fashion. Accordingly, the embodiments described herein may use any appropriately sized and shaped conductor capable of being positioned and oriented in the described manners to electrically connect the various electrical contacts of two adjacent solar cells as the disclosure is not so limited.

Changes in solar cell spacing may occur as a result of many factors, including, but not limited to, mechanical loading and/or thermal cycling. As the solar cell spacing changes during a displacement cycle, forces on the interconnection may cause deformation of the cross-connect wire as opposed to imparting stress into cell surfaces and points of electrical connection which may occur with a standard “S”-style interconnect. During operation, solar cells may be cycled between various extreme temperatures due to changes in environmental temperature as well as temperature changes due to cyclic exposure to sun light. These cyclic temperature changes may also result in cyclic strains and stresses being applied to the various components of interconnected solar cells due to mismatches in thermal expansion of these components. For example, in some embodiments, extreme temperatures a solar module may be subjected to may include temperatures in the range between −40° C. and 85° C. In some cases, a 24-hour period could see one or multiple temperatures cycles over a range of about −20° C. and 43° C. Assuming there is at least one thermal cycle per day, over 20 years a system may undergo a total of about 7,300 thermal cycles. For a period over 40, years, a system may undergo about 14,600 thermal cycles. Without wishing to be bound by theory, the disclosed cross-connect wires may experience less fatigue from the cyclical temperature loading due to better strain relief than traditional “S-style” interconnects.

Embodiments of the interconnection arrangements disclosed herein may operate without breakage for any appropriate number of displacement cycles which may occur during the operational lifetime of an assembly from sources such as thermal cycling, vibration, mechanical loading, and/or any other appropriate source of displacement. In some embodiments, the number of operational cycles a solar cell interconnection may withstand may be greater than 50,000 cycles, 75,000 cycles, 100,000 cycles, and/or any other suitable number of cycles. Correspondingly, a number of operational cycles a solar cell interconnection may withstand may be less than 150,000 cycles, 100,000 cycles, 75,000 cycles, and/or any other suitable number cycles. Combinations of the above noted ranges are contemplated including numbers of cycles withstood between or equal to 50,000 cycles and 150,000 cycles, 50,000 cycles and 75,000 cycles, 75,000 cycles and 150,000 cycles, as well as 50,000 cycles and 75,000 cycles. Of course, any suitable number displacement cycles may be withstood including numbers of cycles greater than or less than those noted above, as the present disclosure is not so limited.

Turning now to the figures, several non-limiting embodiments are described in further detail. It should be understood that the various components, systems, and methods described in relation to the figures may be used either individually and/or in combination as the disclosure is not limited to only the specifically depicted embodiments.

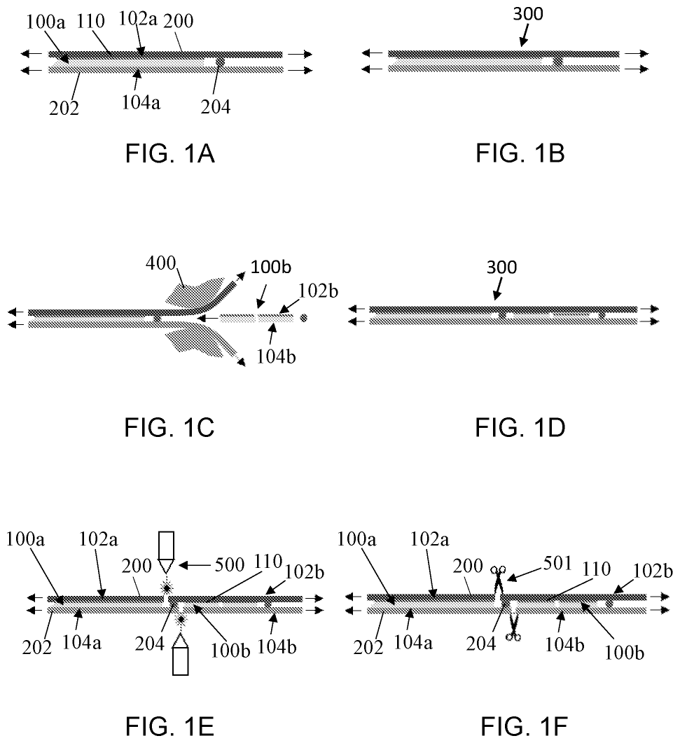

FIGS. 1A-1F depict an embodiment of a solar cell interconnection process. As shown in FIG. 1A, a first solar cell 100a includes a first finger 110 on an upper surface 102a and an electrical contact disposed on a lower surface 104a. In the depicted embodiment, the upper surface corresponds to the sunny side and the lower surface corresponds to the back side. The electrical contact on the lower surface may simply correspond to the lower surface itself as may occur in embodiments where the back surface of a solar cell is a conductive sheet. The first finger is electrically connected to a first interconnection wire 200 disposed on and extending across the upper surface and the electrical contact is electrically connected to a second interconnection wire 202 disposed on and extending across the lower surface. A cross-connect wire 204 is disposed between the first interconnection wire and the second interconnection wire adjacent a side of the solar cell. As shown in FIG. 1B, the first interconnection wire, second interconnection wire, and cross-connect wire are then soldered together, welded (e.g. spot welding), or electrically connected with conductive adhesive to form an electrical assembly 300. As shown in FIG. 1C, ends of the first interconnection wire and second interconnection wire are then spread apart using a spreading tool 400 including optional strain relief. A second solar cell 100b and an optional second cross-connect wire are inserted between the first interconnection wire and second interconnection wire. Accordingly, the first cross-connect wire is disposed between the first solar cell and the second solar cell after this step. In the depicted embodiment, the second solar cell has an approximately identical configuration and orientation to the first solar cell. That is, an upper surface of the second solar cell 102b corresponds to the sunny side and a lower surface of the second solar cell 104b corresponds to the back side. As shown in FIG. 1D, the first interconnection wires and second interconnection wires are closed around the second solar cell. The first interconnection wires are then connected to the fingers on the upper surface of the second solar cell and the second interconnection wires are connected to the one or more electrical contacts on the lower surface of the second solar cell. It should be understood that the depicted method may be repeated such that the interconnection wires may be connected to other electrical contacts and/or cross-connect wires associated with either the same solar cells and/or other solar cells to form an electrical assembly 300 of any desired size or configuration.

As shown in FIG. 1E, a portion of the first interconnection wire 200 and a portion of the second interconnection wire 202 of the electrical assembly 300 may be removed with a laser 500, or other appropriate system capable of removing a portion of the corresponding interconnection wires without damaging the solar panel and/or the electrical connections. Removal of a portion of the first interconnection wire electrically isolates the upper surface 102a and lower surfaces 104a (i.e. sunny and back surfaces) of the first solar cell 100a. Similarly, removal of a portion of the second interconnection wire electrically isolates the lower surface of the first solar cell and the lower surface 104b of the second solar cell 100b. Accordingly, the electrical contact on the lower surface of the first solar cell may be in electrical contact with a finger 110 on the upper surface of the second cell which may place the first and second solar cells in series with one another.

FIG. 1F depicts an alternative embodiment to the step shown in FIG. 1E for removal of a portion of the first interconnection wire 200 and the second interconnection wire 202. In the embodiment shown in FIG. 1F, mechanical cutters remove the portion of the first interconnection wires and second interconnection wires to form the desired electrical connection from the one or more electrical contacts on the lower surface 104a of the first solar cell 100a to the one or more electrical contacts on the sunny surface 102b of the second solar cell 100b.

In some embodiments, the method for interconnecting solar cells shown in FIGS. 1A-1F may be a continuous process. That is, solar cells may be continuously inserted and electrically connected with cross-connect wires between each cell. The first interconnection wires and second interconnection wires may then have material removed to create a fully wired solar module. Alternatively, in certain embodiments, multiple rows of solar cells may be interconnected according to the embodiment depicted in FIGS. 1A-1F. That is, multiple processes may run parallel to each other, with the cross-connect wire electrically connecting the rows in a direction transverse to the first interconnection wires and the second interconnection wires. In some embodiments, the steps may be reordered, such as electrically connecting all interconnection wires and multiple cells first and leaving the interconnection wire removal for a collective final step, as the present disclosure is not so limited.

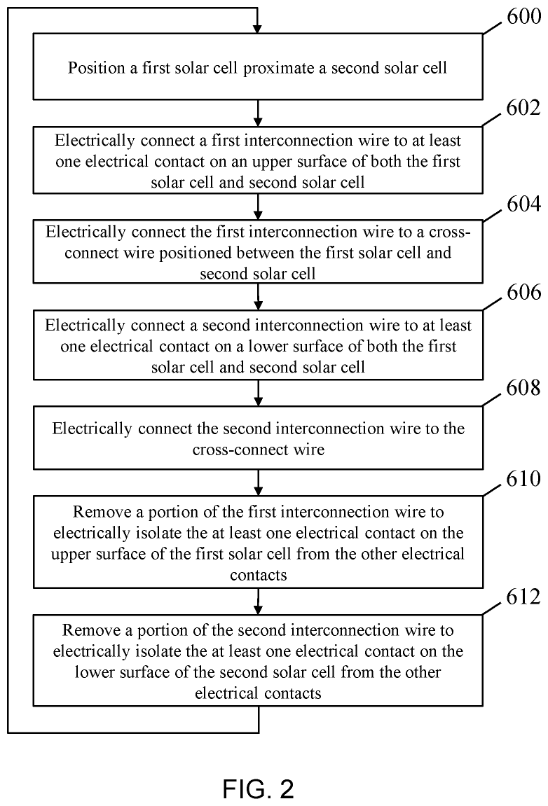

FIG. 2 is a block diagram of one embodiment of an interconnection process for solar cells. At block 600, a first solar cell is positioned proximate a second solar cell. The first solar cell may positioned close to the second solar cell with a predetermined cell spacing. At block 602, a first interconnection wire is electrically connected to at least one electrical contact on an upper surface of both the first solar cell and the second solar cell. In some embodiments, the at least one electrical contact on an upper surface of both the first and second solar cells may be arranged as at least one finger. At block 604, the first interconnection wire is electrically connected to a cross-connect wire which is positioned between the first and second solar cells within the confines of the solar cell spacing. At block 606, a second interconnection wire is electrically connected to at least one electrical contact on the lower surface of both the first and solar cells. At block 608, the second interconnection wire is electrically connected to the cross-connect wire, to bring all of the at least one electrical contacts on both the upper and lower surfaces of both the first and second solar cells into electrical communication with one another. According to the embodiment shown in FIG. 2, electrically connecting the interconnection wires, electrical contacts, and the cross-connect wire includes spot welding, soldering, applying a conductive adhesive, or other appropriate method. The electrical connections between the cross-connect and interconnection wires may either be done individually as shown in the block diagram and/or an electrical connection between a cross-connect wire and two adjacent interconnection wires may be done simultaneously as the disclosure is not limited in this fashion. At block 610, a portion of the first interconnection wire is removed to electrically isolate the at least one at least one electrical contact on the upper surface of the first solar cell from the other electrical contacts. At block 612, a portion of the second interconnection wire is removed to electrically isolate the at least one electrical contact on the lower surface of the second solar cell from the other electrical contacts. As a result of the interconnection process of FIG. 2, the at least one electrical contact on the lower surface of the first solar cell may be in electrical communication with the at least one electrical contact on the upper surface of the second solar cell, effectively interconnecting the solar cells and replacing a conventional “S”-style interconnect.

In some embodiments, the process of FIG. 2 may be a continuous process and/or may be performed simultaneously in multiple threads. For example, in the case where a solar cell interconnection process is used during a manufacturing process in a manufacturing line, the process may be automated and performed in continuous manner. Additionally, multiple solar cells may be interconnected at the same time in multiple threads to form a solar cell module. In some embodiments, the process of FIG. 2 may be performed simultaneously in multiple threads to form a single solar cell interconnection. For example, a solar cell interconnection may include multiple interconnection wires disposed on and extending across both the upper and lower surfaces of both the first and second solar cell. Accordingly, multiple interconnection wires may be electrically connected to electrical contacts and/or the cross-connect wire at the same time. Similarly, multiple portions of the plurality of interconnect wires may be removed at the same time.

In addition to the above, it should also be noted that while FIG. 2 has indicated that first and second solar cells may be placed proximate to one another prior to connecting the interconnection wires to the first solar cell and electrically connecting the interconnection wires to a cross connect wire disposed between the first and second solar cells, these steps may be performed in any appropriate order. For example, as described above in regards to FIGS. 1A-1F, the interconnection wires and cross connect wire may be positioned and electrically connected to each other and the first solar cell prior to placing the second solar cell adjacent to the first solar cell. The electrical connections between the interconnection wires and the second solar cell may then be formed after appropriately placing the second solar cell in the desired position. Accordingly, it should be understood that the described steps may be performed in any appropriate order as the disclosure is not limited to any particular ordering of the described steps.

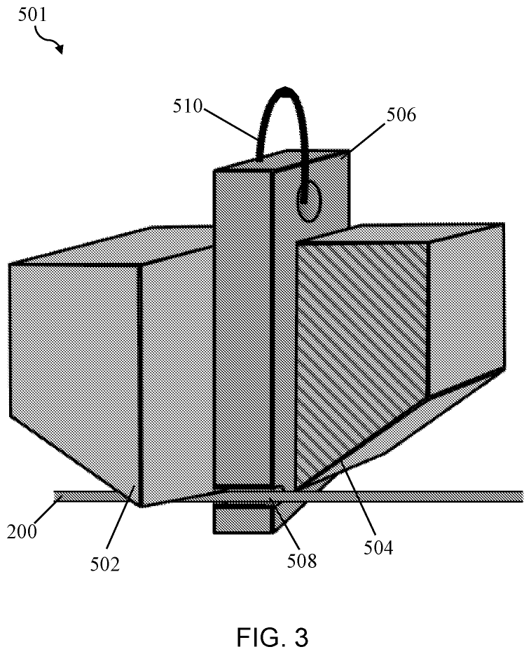

FIG. 3 depicts one embodiment of a mechanical wire cutter 501. As shown in FIG. 3, the mechanical wire cutter includes a first outer blade 502, a second outer blade 504 shown in a cross sectional view for illustrative purposes, and an inner blade 506 disposed between the first and second outer blades. The inner blade includes an indentation 508 formed in a bottom portion of the inner blade. The inner blade may be slidably disposed in between the first outer blade and the second outer blade so that the inner blade may translate in a vertical direction relative to the first and second outer blades. In some embodiments, the inner blade may also move in a lateral direction though embodiments in which the entire mechanical cutter assembly may be configured to translate in a lateral direction are also contemplated. As shown in FIG. 3, the inner blade is in a first extended position where the indentation is positioned distally outwards from the corresponding cutting edges of the first outer blade and the second outer blade. In the first extended position, the indentation is available to the interconnection wire 200, which may be received in the indentation. After the interconnection wire 200 is received in the indentation 508, the inner blade 506 may be moved to a second retracted position where the indentation is between the first outer blade and the second outer blade. As the inner blade is moved towards the second retracted position, the interconnection wire 200 is sheared against the cutting edges of the first and second outer blades 502, 504 by the indentation. The inner blade 506 may be connected to an actuator (not shown in the figure) by any appropriate coupling 510. The actuator may selectively move the inner blade between the first extended position and the second retracted positioned. However, as noted previously, embodiments in which the first and second outer blades are moved relative to a stationary inner blade are also contemplated as the disclosure is not limited in this fashion.

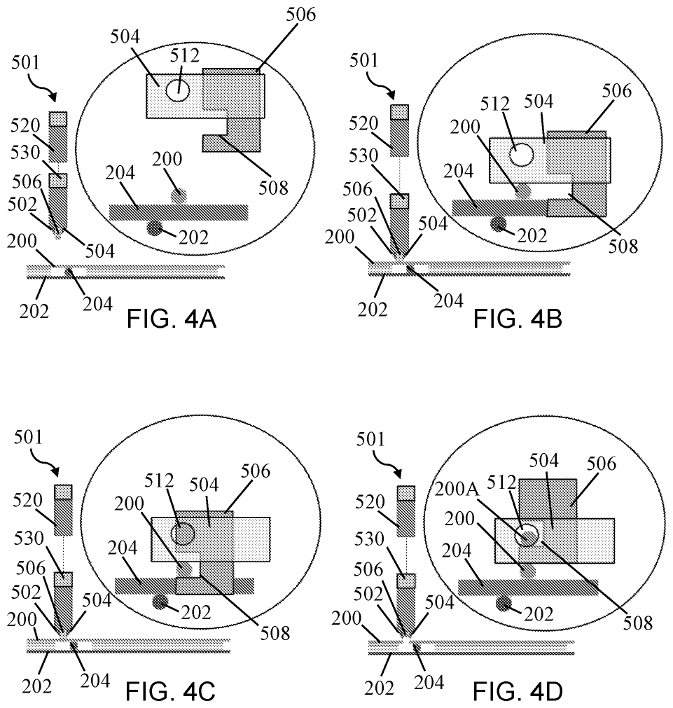

FIGS. 4A-4D depict one embodiment of a cutting process for interconnection wires. As shown in FIG. 4A, the mechanical wire cutter 501 includes a first outer blade 502, second outer blade 504 and an inner blade 506 with an indentation 508 as previously described. The cutting process may be performed on solar cells which may include a first interconnection wire 200 disposed on and extending across an upper surface of a first and second solar cell, and a second interconnection wire 202 disposed on and extending across a lower surface of a first and second solar cell. The first and second interconnection wires are electrically connected to a cross-connect wire 204. The mechanical wire cutter 501 may include a first actuator 520 arranged to translate the inner blade 506 and/or the first and second outer blades 502, 504 in a vertical direction relative to the interconnection wires. The mechanical wire cutter may also include a second actuator 530 arranged to translate the inner blade and/or the first and second outer blades in a vertical direction relative to one another.

In FIG. 4A, the mechanical wire cutter 501 is in a first position with all of the blades out of contact with the first interconnection wire 200, and the inner blade 506 is in a first extended position with the indentation 508 located outside of the first and second outer blades 502, 504. In FIG. 4B, the mechanical wire cutter is moved to a second position by the first actuator 520 where the cutting edges of the first and second outer blades 502, 504 are in contact, or at least in close proximity, with the first interconnection wire 200. The inner blade 506 is still in a first extended position and is also in a first lateral position where the first interconnection wire 200 is outside of the indentation 508. As the first and second outer blades form the cutting edges to cut the interconnection wire, keeping the outer blades in contact with an interconnection wire may reduce the amount of deformation and/or strain experienced by the interconnection wire during a cutting process. In some embodiments, a mechanical wire cutter may be arranged to keep the first and second outer blades within at least 150 μm of an interconnection wire while the wire is being cut.

In the embodiment shown in FIG. 4B, the mechanical wire cutter 501 may include a contact sensor arranged to determine the position of the first and second outer blades 502, 504 relative to the first interconnection wire 200. For example, the contact sensor may include a voltage generator which applies a non-zero voltage across the first outer blade and the second outer blade. According to this embodiment, when the first and second outer blades come into contact with the first interconnection wire 200, a circuit will be completed between the first and second outer blades which may cause a detectable decrease in voltage between the first and second outer blades. Such a voltage decrease may be indicative of contact between the interconnection wire and the first and second outer blades. Of course, the contact sensor may employ any suitable arrangement, including optical sensors, linear encoders, or other position determining sensors as the present disclosure is not so limited.

After contacting an interconnection wire 200 to be cut with the mechanical wire cutter 501 as shown in FIG. 4C, the inner blade 506 may be moved from a first lateral position to a second lateral position relative to the first and second outer blades 502 and 504. This lateral movement of the inner blade may move the indentation 508 such that the interconnection wire 200 is disposed in the indentation 508. Of course, embodiments in which the entire mechanical cutter, and not just the inner blade, is moved to place a wire in the indentation are also contemplated. Additionally, in another embodiment, the first and second solar cells of an assembly may be arranged to move between a first lateral position and a second lateral position to place a wire in a corresponding indentation of a mechanical wire cutter. According to this embodiment, a mechanical wire cutter 501 may remain stationary in a lateral direction and the first and second solar cells may be arranged to translate an interconnection wire 200 into the indentation 508 when the inner blade 506 is in a first extended position (see FIGS. 4A-4C). Thus, the mechanical wire cutter 501 may move in one dimension which may reduce the number actuators used with the mechanical wire cutter.

In the embodiment of FIGS. 4A-4D, the indentation 508 is square and is sized appropriately to receive the interconnection wire. However, in some embodiments, it may be desirable for an indentation to have a shape corresponding to that of the interconnection wire to be cut to help with indexing and holding a wire during a cutting process. For example, the indentation may be circular for receiving a circular wire, or polygonal for receiving a wire with a polygonal cross-section. Of course, an indentation may have any suitable shape, including, but not limited to, square, rectangular, triangular, circular, pentagonal, or any other suitable shape.

After positioning a wire in an indentation of a mechanical wire cutter, as shown in FIG. 4D, the inner blade 506 may be moved from a first extended position to a second retracted position. In such a configuration, the indentation 508 has been moved between the first outer blade 502 and the second outer blade 504. As the indentation shears the interconnection wire 200 against the corresponding cutting edges of the first and second outer blades, the blades cut a portion 200A of the interconnection wire which remains disposed inside of the indentation 508 between the first and second outer blades. According to the embodiment of FIGS. 4A-4D, the first and second outer blades may be aligned so that each blade cuts the corresponding location of the interconnection wire simultaneously as the inner blade is moved toward the second retracted position. Again, such an arrangement may minimize the stresses and deformations applied to the overall interconnection wire during a cutting process. Accordingly, the remaining interconnection wire 200 connected to an associated solar cell may stay substantially intact and non-deformed by the cutting process.

As shown in FIG. 4D, in some embodiments either the first outer blade 502 and/or the second outer blade 504 may include a wire removal hole 512 which is aligned with the indentation 508 when the inner blade is in the second retracted position. Accordingly, the wire removal hole may provide access to the indentation and the wire portion 200A disposed therein. Compressed air, a mechanical pusher, or any other suitable arrangement may be used to remove the wire portion 200A from the indentation 508 so that a mechanical cutting process may be performed again by the mechanical wire cutters 501. In some embodiments, both the first outer blade and the second outer blade may include a wire removal hole to provide additional access to the indentation when the inner blade is in the second retracted position.

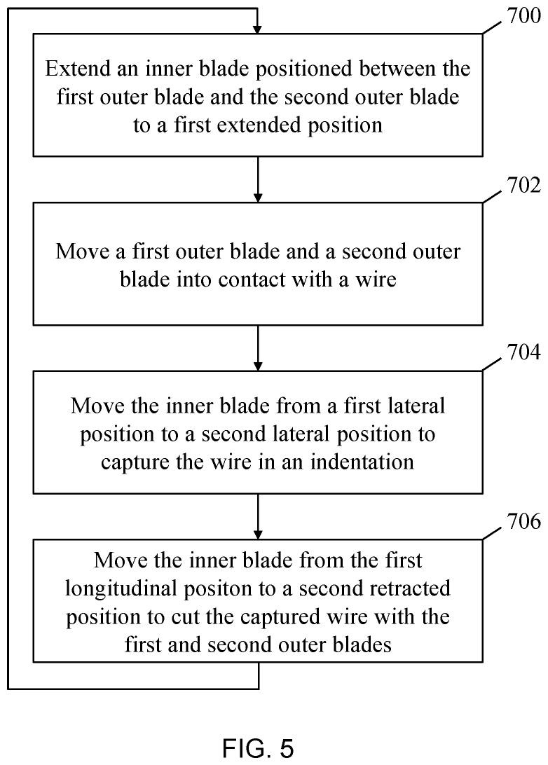

FIG. 5 is a block diagram of one embodiment of a wire cutting process. At block 700, an inner blade is extended to a first extended position, where the inner blade extends out from and is disposed between first and second outer blades. At block 702 the first outer blade and/or second outer blade are moved into contact with a wire. At block 704, the inner blade and the outer blades may be moved together from a first lateral position to a second lateral position to capture the wire in an indentation formed in the inner blade. Alternatively, in some embodiments as noted above, the inner blade may be moved laterally relative to the first and second outer blades to position the wire in the indentation. At block 706, the inner blade is moved from the first extended position to a second retracted position to cut the captured wire with the first and second outer blades. The process shown in FIG. 5 may be a continuous process and may be performed simultaneously using multiple mechanical wire cutters in multiple locations for multiple wires disposed between any number of associated solar cells.

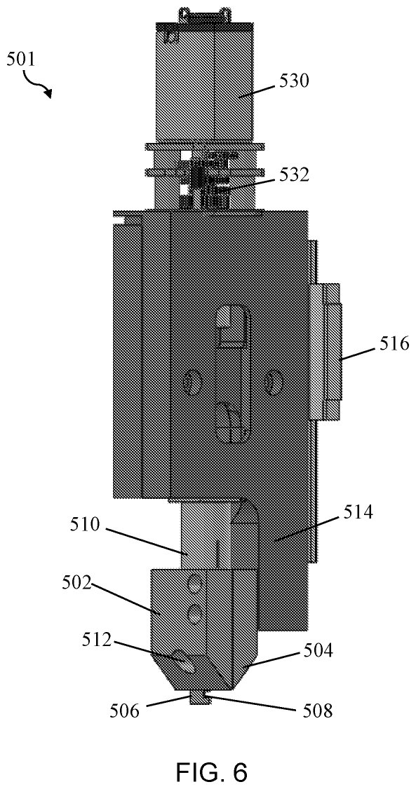

FIG. 6 depicts another embodiment of a mechanical wire cutter 501. As shown in FIG. 6 and as discussed previously, the mechanical wire cutter includes a first outer blade 502, a second outer blade 504, and an inner blade 506 slidably disposed between the first and second outer blade. The first and second outer blades are rigidly mounted to a chassis 514, while the inner blade is mounted to an actuator 530 via a coupling 510. For example, the actuator may include a gear box which turns an associated screw such that a nut disposed on the screw and connected to the coupling may axially displace the inner blade. However, it should be understood that the mechanical wire cutter may include any appropriate transmission 532 to convert a provided linear and/or rotational energy of the actuator 530 into linear motion of the coupling and the inner blade. The actuator 530 and transmission 532 may be attached to the chassis. The chassis may also be connected to one or more linear slides 516 which may be used to permit movement of the mechanical wire cutter in a vertical, lateral, and/or other appropriate direction in response to actuation of one or more other actuators, not depicted. Accordingly, it should be understood that one or more other actuators may be attached to a mechanical wire cutter to control overall movement of the mechanical wire cutter in one or more directions. For example, the mechanical wire cutter may be constructed and arranged to move in one or more of a vertical and/or lateral direction relative to an underlying solar cell assembly. Operation of the depicted mechanical wire cutter may be similar to the previously described embodiments.

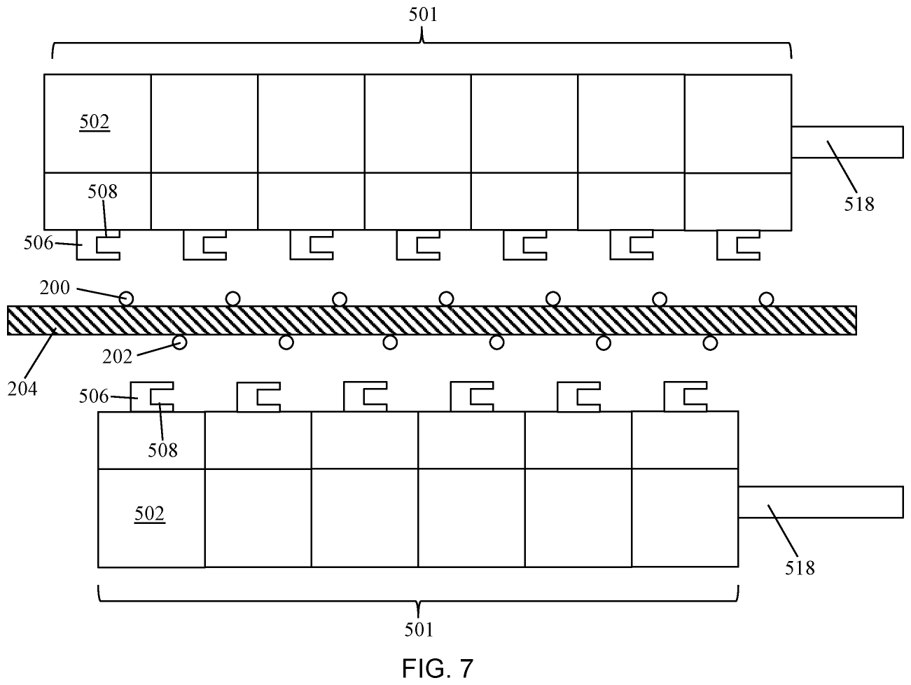

FIG. 7 depicts one embodiment of a mechanical wire cutter array in a first position. As shown in FIG. 7, a plurality of mechanical wire cutters 501 may be arranged in a linear array adapted to remove multiple portions of interconnection wire from a solar cell simultaneously. Each of the mechanical wire cutters may be controlled to move in the same way at the same time. Accordingly, such an array may drastically reduce the time used to interconnect solar cells with multiple interconnection wires. As also shown in the figure, in some embodiments, multiple mechanical wire cutter arrays may be associated with different sets of interconnection wires. For example, a first array may be positioned on an upper surface of a solar cell module and a second array may be positioned on a lower opposing surface of the solar cell module. Accordingly, when the arrays are located in a first position as shown in FIG. 7, each of the mechanical wire cutters may be positioned away from a first interconnection wire 200, a second interconnection wire 202, and a cross-connect wire 204. An inner blade 506 of each of the mechanical wire cutters may also be in a first extended position with an indentation 508 outside of the first outer blade 502. As shown in FIG. 7, each of the mechanical wire cutter arrays is connected to a chassis coupling 518 which is adapted to couple the array to actuators which may move the array in multiple directions (e.g., laterally and vertically). The inner blades 506 of the mechanical wire cutters may be spaced appropriately to match the spacing between interconnection wires. In some embodiments, the inner blades may be spaced apart from one another a distance between or equal to approximately 5 mm and 20 mm, 2.5 mm and 10 mm, and/or any other appropriate distance.

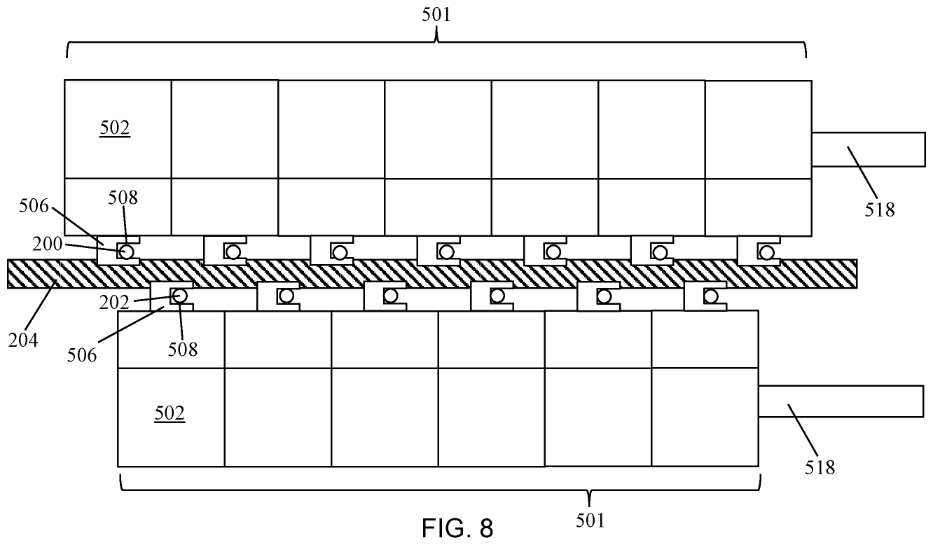

FIG. 8 depicts the mechanical wire cutter array of FIG. 7 in a second position. In the second position shown in FIG. 8, the mechanical wire cutter arrays have been moved into close proximity in a vertical direction such that the cutting edges of the associated first outer blade 502 and second outer blade, not shown, are in contact with the interconnection wires 200 and 202. Alternatively, each individual mechanical cutter may include a vertical actuator that may be used to individually control the vertical position of the separate mechanical wire cutters relative to an associated wire. Once appropriately positioned in a vertical direction, the inner blade 506 of the individual mechanical cutters, the combined inner and outer blades of each assembly, and/or the overall array of mechanical cutters may be translated in a lateral direction to capture each of the associated first and second interconnection wires 200, 202 inside of the corresponding indentation 508 of each of the inner blades 506. Accordingly, in this position the inner blades 506 are each in a first extended position as well as a second lateral position with a wire retained in the indentation of each inner blade. Each of the inner blades may then be retracted simultaneously toward a second retracted position to remove portions of each of the first and second associated interconnection wires in order to complete a solar cell interconnection.

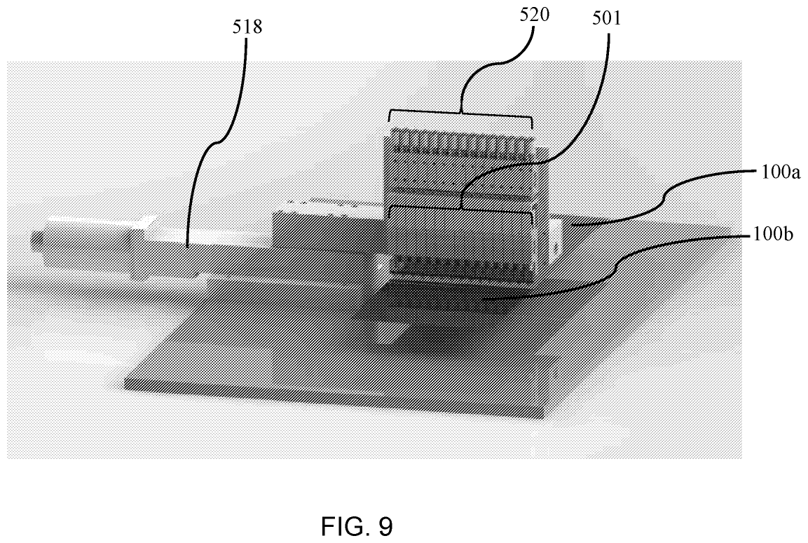

FIG. 9 depicts yet another embodiment of a mechanical wire cutter array including a plurality of mechanical wire cutters 501. As shown in FIG. 9, a first solar cell 100a and a second solar cell 100b are in position beneath the mechanical wire cutter array so that the mechanical wire cutter array may remove portions of each of the interconnection wires disposed on and extending across an upper surface of the first and second solar cells. The plurality of mechanical wire cutters are each provided with one or more actuators 520 operatively coupled to the associated blade assembly and/or inner blade of each mechanical wire cutter to individually control actuation of the separate mechanical wire cutters and/or to separately control a vertical height of the individual mechanical wire cutters relative to an associated wire. Accordingly, the mechanical wire cutters may be operated as a single unit, or each of the mechanical wire cutters may be operated independently or in sequence with one another. As shown in FIG. 9, the mechanical wire cutter array is linked to a chassis coupling 518 which may be used to link the mechanical wire cutter array to one or more actuators which may translate the mechanical wire cutters in one or more lateral and/or vertical directions relative to the solar cells.

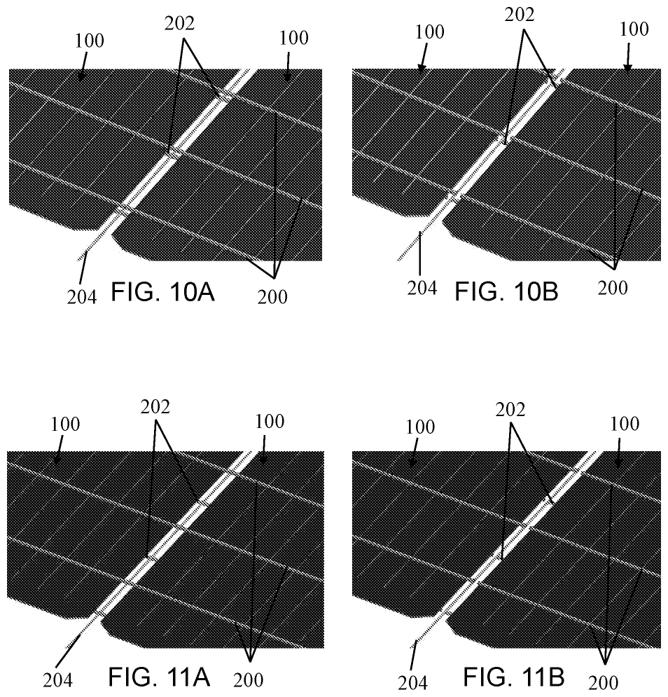

FIGS. 10A-10B depict another embodiment of a solar cell interconnection process. FIG. 10A depicts a rendering of adjacent solar cells with a cross-connect wire 204 and aligned interconnection wires 200, 202 prior to trimming. FIG. 10B depicts the embodiment shown in FIG. 10A after portions of the interconnection wires are removed (i.e., trimmed). According to the depicted embodiment, the sunny side interconnection wire 200 may include a prismatic cross-section. Without wishing to be bound by theory, such an arrangement may improve light trapping as previously described.

FIGS. 11A-11B depict yet another embodiment of a solar cell interconnection process. FIG. 11B depicts a rendering of adjacent solar cells with a cross-connect wire 204 and offset interconnection wires 200, 202 prior to trimming. That is, the second side (i.e. back side) interconnection wires 202 are parallel but not collinear with first side (i.e., sunny side) interconnection wires 204. Such an arrangement may improve resistance to thermal cycling as previously described. FIG. 11B depicts the embodiment shown in FIG. 11A after portions of the interconnection wires are removed (i.e., trimmed).

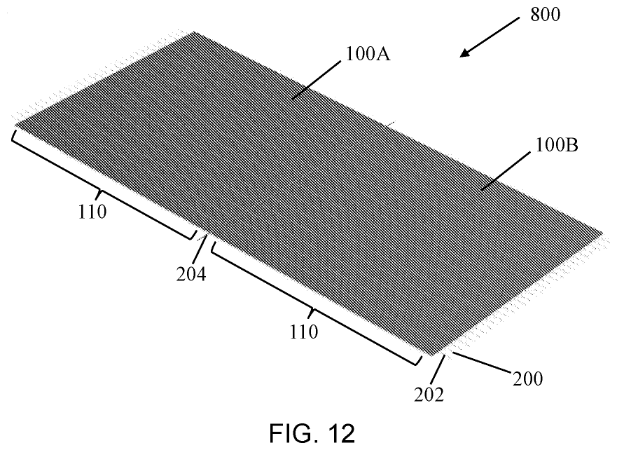

FIG. 12 depicts one embodiment of an assembly 800 of solar cells 100 including a solar cell interconnection. As shown in FIG. 12, two adjacent cells are interconnected using an exemplary embodiment of a method of interconnecting as disclosed herein. The assembly includes independent first interconnection wires 200 disposed on and extending across upper surfaces of each of the solar cells 100A and 100B and second interconnection wires 202 disposed on and extending across lower surfaces of the each of the solar cells. In some embodiments, the first and second sets of interconnection wires may be offset from each other such that they are not located in the same vertical planes perpendicular to a surface of the associated solar cells as described previously above. As shown in FIG. 12, the first interconnection wires electrically interconnect a plurality of fingers 110 disposed on the upper surfaces of each of the solar cells. A cross-connect wire 204 is positioned between the solar cells and electrically connects the first interconnection wires to the second interconnection wires to electrically connect opposing surfaces on the first and second solar cells as previously discussed. Removed portions of interconnection wire produce the electrical interconnection from positive-to-negative contact areas between the opposite surfaces on the solar cells.

### Example: Deformation Analysis of Cross-Connect and Interconnection Wires

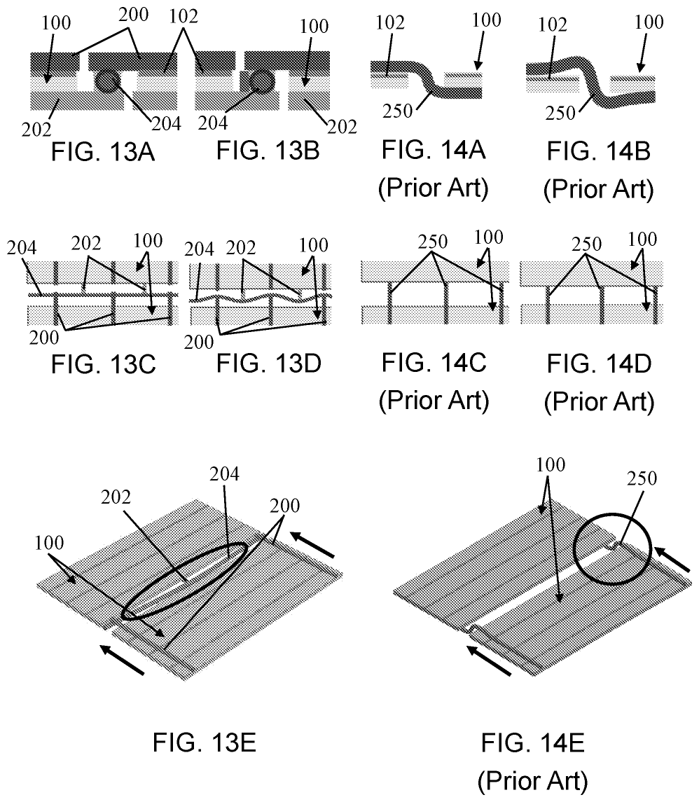

FIGS. 13A-13E depict an embodiment of a solar cell interconnection. FIGS. 13B, 13D, and 13E shows expected wire deformation when using offset first interconnection wires and second interconnection wires with a cross-connect wire. According to the depicted embodiment, it is assumed that the solar cells in a module can move toward each other or away from each other (i.e., the cells have one degree of freedom). For simplicity, in this embodiment, the solar cells do not slide relative to each other (i.e. from a sunny side perspective, the interconnection wires connecting the sunny sides and back sides of the cells remain substantially parallel and linear).

As shown in FIG. 13A, the proposed cell interconnection is shown in an undisturbed state. That is, the solar cells are at a designed spacing where the first interconnection wires 200, offset second interconnection wires 202, and cross-connect wire 204 are not under significant stress. FIG. 13C also shows a top view of the cell interconnection in an undisturbed state. As shown in FIG. 13B, when the solar cells are moved closer together the cross-connect wire is deformed while the rest of the system remains relatively undisturbed. That is, as the cells are displaced, the sunny side and back side interconnection wires will push or pull on the cross-connect wire in opposing directions. In an embodiment where these two sets of interconnection wire are collinear, the interconnection would exhibit bending into and out of the planes of the cell faces similar to the “S”-style interconnection (for example, see FIGS. 14A-14E). Instead, as shown best in FIG. 13D, the offset first interconnection wires and second interconnection wires push or pull the cross-connect wire such that it bends like a beam. Without wishing to be bound by theory, concentrating the displacements into the cross-connect wire may reduce the stress imparted into the cell, thereby giving the cell a lower chance of developing cracks and breakage. FIG. 13E depicts a perspective view of two solar cells undergoing relative displacement as indicated by the arrows. As discussed above, the cross-connect wire bends like a beam between the first side and second side offset interconnection wires.

FIGS. 14A-14E depict a conventional solar cell interconnection. As shown in FIG. 14A and FIG. 14C, the “S”-style cell interconnection 250 is shown in an unstressed condition where each solar cell 100 has proper design spacing. According to this embodiment, if the cells are pushed toward each other, the system must deform at the interconnecting interconnection wires (see FIGS. 14B and 14D-14E). Since these interconnection wires are snaked from the upper surface of one cell to the lower surface of the next cell, the interconnection wires will pull or push on these opposing surfaces. Without wishing to be bound by theory, the largest stresses in this system are apparent at the electrical connection between the first finger or electrical contact and the interconnection wire, and subsequently the area of the cell around this electrical contact. By imparting large stresses upward or downward into the sides of the cell, there is a higher chance of cracks, breakage, and decreased efficiency of the solar cells.

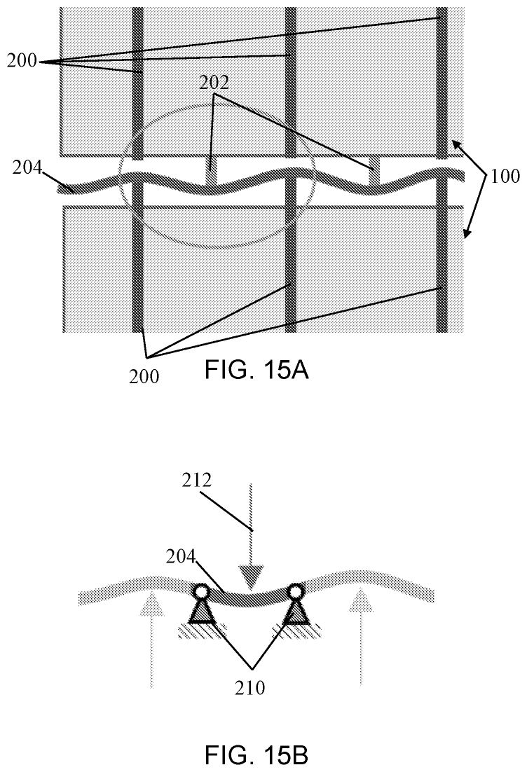

FIGS. 15A-15B depict an embodiment of a solar cell interconnection model. In order to determine an optimal offset range and to verify the benefits of embodiments disclosed herein, a model of the first interconnection wire, second interconnection wire, and cross-connect wire was created. To assess the possibility of the sunny side (i.e., upper surface) or back side (i.e., lower surface) interconnection wires buckling, the unsupported length of interconnection wire was approximated as a column. A calculation of Euler's critical load gives the maximum load a column can withstand while staying straight, and is given in the following equation:

P_{cr}=(π²EI)/(KL)²

where P_{cr} is Euler's critical load at which buckling will occur, E is the modulus of elasticity of the column, I is the moment of inertia of the column, L is the unsupported length, and K is the effective length factor.

In order to determine if the sunny side interconnection wire or back side interconnection wire will buckle, the forces on the cross-connect wire were modeled. As illustrated in FIG. 15A, the sunny side and back side interconnection wires were offset such that cell displacements caused the deformation of the cross-connect wire. To minimize peak stresses, the interconnection wires may be modeled to be symmetrically offset with even spacing between each adjacent wire (e.g., 5 mm offset if two sets of 23 interconnection wires are used with each independent set having 10 mm wire spacing). Of course, the interconnection wires may be offset with any suitable spacing, as the present disclosure is not so limited. For example, the first side and second interconnection wires may be offset from one another by 2.5 to 7.5 mm. For this example range and other ranges described herein, the offset may correspond to percentage offsets from the spacing of one of the first side and second interconnection wires. That is, the first side and second interconnection wires may be offset from one another by 25% to 75% of the spacing between the first interconnection wires or the second interconnection wires. As shown in FIG. 15B, the first interconnection wires, second interconnection wires, and cross-connect wires may be modeled as simple beam bending using corresponding equations. According to this model, the centers of the unsupported portions of the cross-connect wires become pinned boundary conditions 210 since the cross-connect wire does not translate due to symmetry but can rotate. Additionally, the first or second interconnection wire at the center can be represented by its point force contribution perpendicular 212 to the cross-connect wire.

According to the model depicted in FIGS. 15A-15B and without wishing to be bound by theory, the maximum deflection of the cross-connect wire 204 occurs at the center, where the first side or second interconnection wire point force were modeled. Assuming the interconnection wire does not buckle, the deflection will be equivalent to the change in cell spacing. Accordingly, wire deflections were calculated analytically using standard beam bending equations. By using a factor of safety of two ±100 μm displacements were used for the change in cell gap, which corresponding to ±50 μm deflections in our model. One result from choosing a wire diameter of 200 μm, copper modulus of elasticity of 110 GPa, and 5 mm offset between interconnection wires yielded a calculated point force of roughly 0.17 N according to the model. By solving for the force in the wire as discussed above, a direct comparison was made to see whether the modeled force was above the critical buckling force. According to the computed model, the critical buckling force was over two orders of magnitude greater than the calculated force occurring in the interconnection wire with ±100 μm, which suggests the vast majority the deformation occurs in the cross-connect wire.

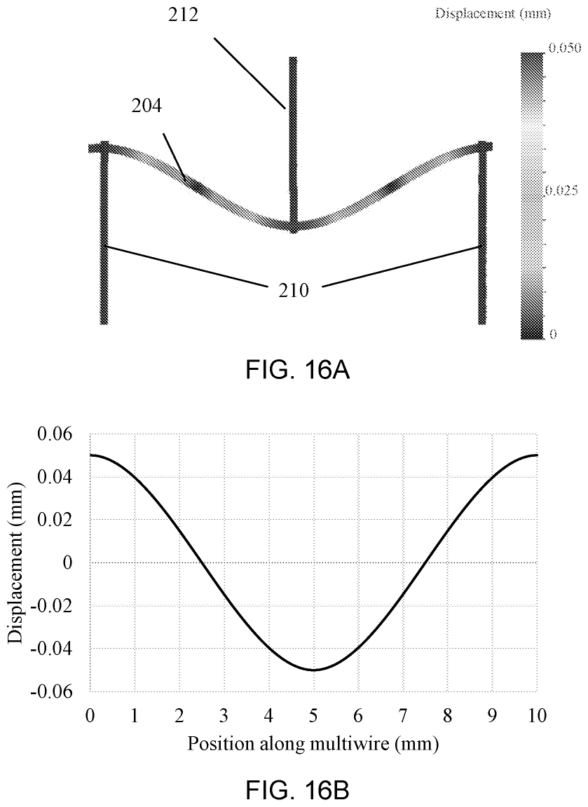

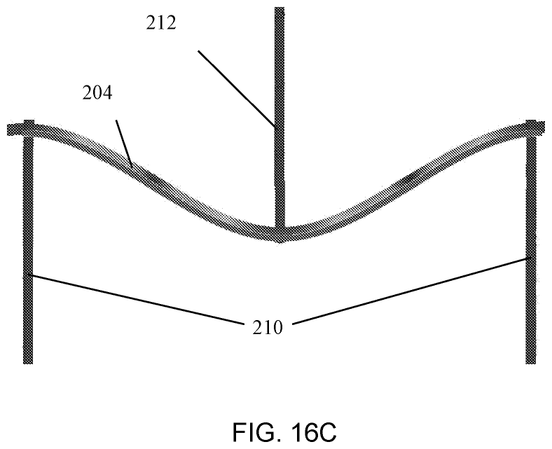

FIGS. 16A-16C depict finite element analysis (FEA) of the solar cell interconnection of FIGS. 15A-15B. To assess the accuracy of the analytical model as discussed above, FEA was performed without an encapsulant, the results of which are shown in FIGS. 16A-16C. FIG. 16A shows results of the FEA and FIG. 16B shows a graph of calculated deformations. From comparison of FIGS. 16A and 16B, it was clear the model accurately predicted the behavior of the interconnected wires. FIG. 16C shows the two models superimposed, demonstrating that both models agree upon the bending mode of the cross-connect wire without encapsulant. According to the results shown in FIGS. 16A-16C, stresses in both analytical and FEA models showed the maximum stress in the cross-connect wire to be at the interconnection wire and cross-connect wire joint. The maximum stress at this point is about 270 MPa.

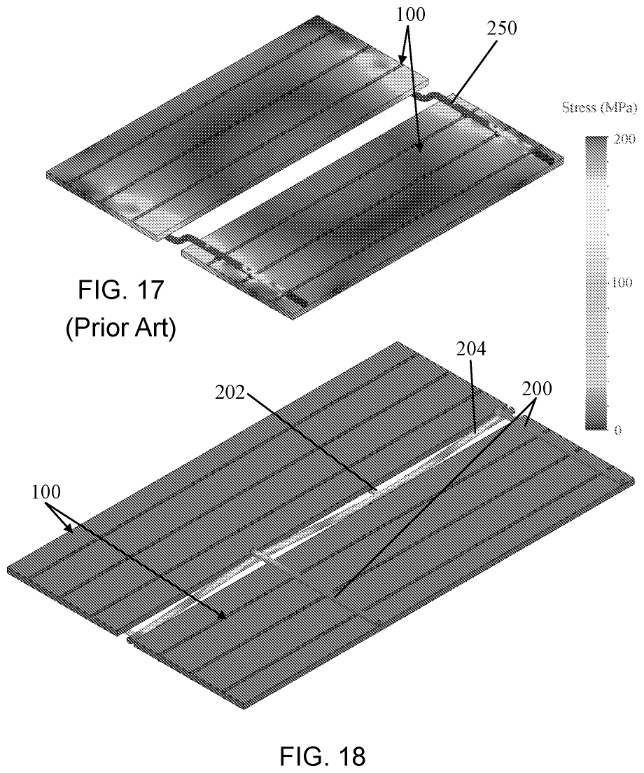

To further validate the hypothesis that the disclosed interconnection redirects displacements into the cross-connect wire, additional FEA results are shown in FIG. 17 and FIGS. 17 and 18. These computational models show that the proposed method of interconnection shown in FIG. 18 redirects deformations from cell displacements into the cross-connect wire 204 instead of the solar cells 100. In comparison to the conventional interconnection shown in FIG. 17, peak stresses in the interconnection and solar cell are vastly reduced. That is, in the “S”-style interconnection of FIG. 17, there are considerably larger stresses in the wire between cells and at the soldered connection to the first finger. Direct comparisons can be made to the proposed interconnection and relatively unharmed cell in FIG. 18, with the large stresses appearing in the cross-connect wire as opposed to the cell.

### Example: Deformation Analysis of Encapsulated Solar Module

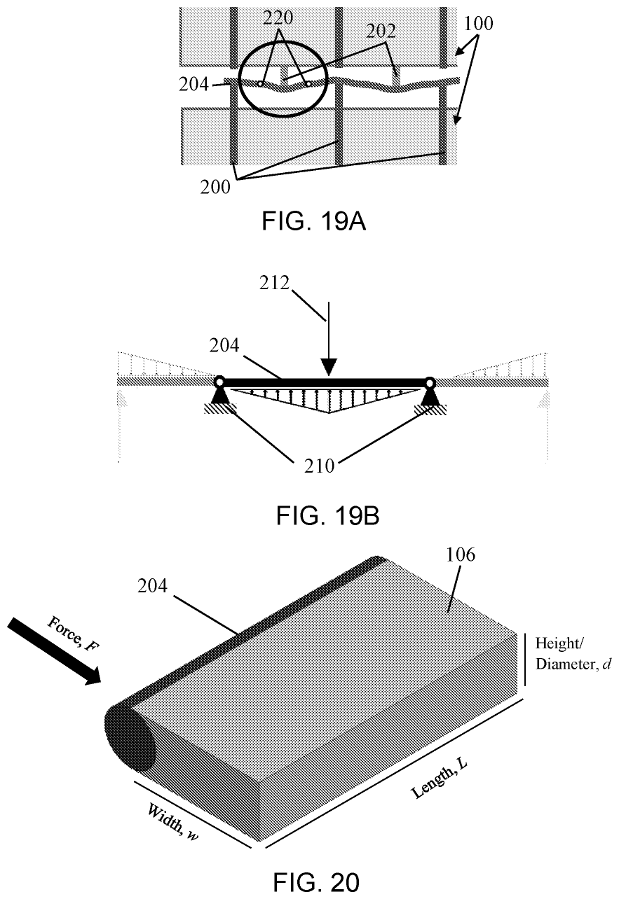

FIGS. 19A-19B depict yet another embodiment of a solar cell interconnection. In the models depicted in FIGS. 15A-18 and discussed above, the cross-connect wires do not include any encapsulation. Accordingly, these models did not account for the additional restraints of an encapsulant on the interconnection and solar cell system. To examine the effects of encapsulating the system, analytical models and FEA were performed again including encapsulation.

In some embodiments, to find the bending mode of the cross-connect wire when the cells and interconnect are encapsulated, the cross-connect wire was assumed to bend as if it were a cylindrical beam with pinned boundary conditions. Without wishing to be bound by theory, such a model may include most parameters from the previously discussed model. That is, the dimensions of the interconnection wire and cross-connect wire are the same, the unsupported length of cross-connect wire is the same, the interconnection wire at the center simulated as a point load, and the pinned boundary conditions where the cross-connect wire can rotate but not translate is the same. However, in contrast to the previously discussed models, additional loads were distributed along the length of the cross-connect wire from the encapsulant.

In some embodiments, at equilibrium the cross-connect wire may be straight and parallel to the interconnected solar cell side surfaces. The encapsulant (e.g., ethylene vinyl acetate) may surround this equilibrium state. Accordingly, if adjacent cells displace towards or away from each other, the encapsulant adds resistance which is modeled as a distributed load on the cross-connect wire. Without wishing to be bound by theory, the load is not evenly distributed, but rather the portions of wire which move the most will encounter the highest resistance which results in a different bending profile as shown in FIG. 19A. According to one embodiment, linearly increasing (triangular) loads are used to model the encapsulant, a drawing of which is shown in FIG. 19B. The beam bending corresponding to the four triangular distributed loads and point load may be calculated independently and superposition is used to produce the overall deformation.

FIG. 20 depicts an embodiment of an encapsulated interconnection. As shown in FIG. 20, a model is created to estimate the order of magnitude of the force. The distributed loads have units of force per unit length, and accordingly the model in FIG. 20 may be used to estimate the distributed loads. The stress in the cross-connect wire 204 is proportional to the force divided by unit area, and the unit area is approximately the diameter of the cross-connect wire multiplied by its length. Strain is equal to stress divided by elastic modulus, and the displacement is equal to strain multiplied by the width. Therefore, the force per unit length is the displacement, diameter, and modulus multiplied together and divided by the width. For example, if it is assumed each “beam” of cross-connect wire deforms 50 μm, the diameter is 200 μm, modulus of the EVA is a constant 10 MPa, and width is 0.4 mm, we estimate the distributed load to be 250 N/m. In some cases, the load may be greater due to additional resistance from the EVA which fully encases the wire.

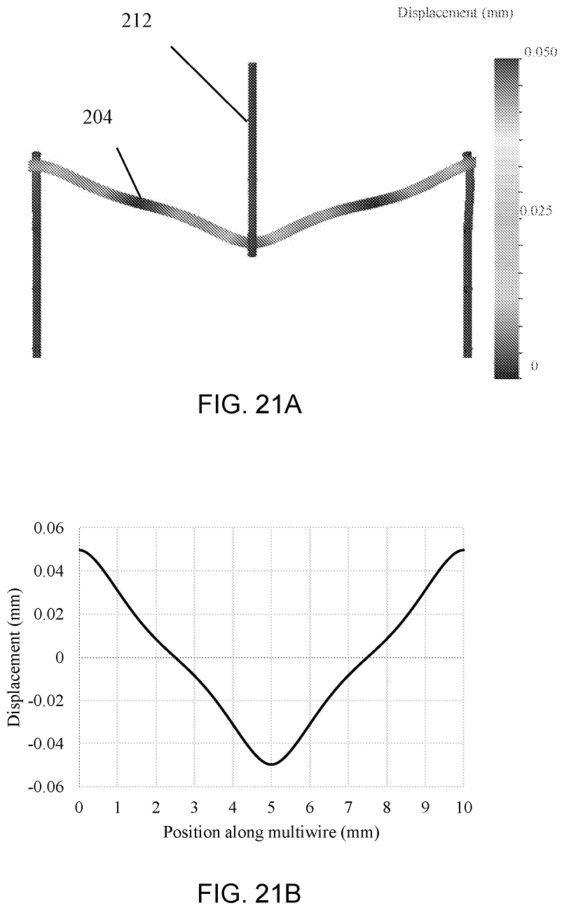

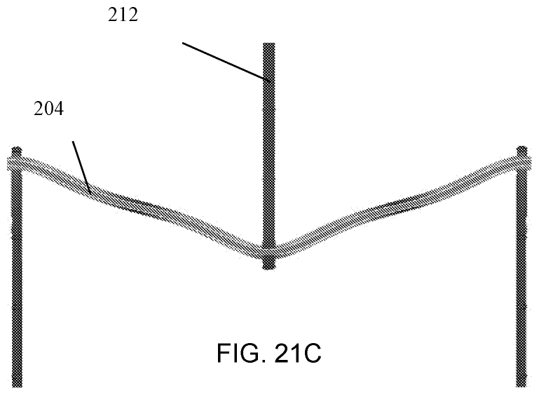

FEA was performed to assess the accuracy of the bending that will occur at this interconnect including encapsulation, the results of which are shown in FIGS. 21A-21C. Using the 10 MPa constant modulus of elasticity for EVA, the deformation is shown in FIG. 21A. FIG. 21B illustrates the expected results from the analytical model, and FIG. 21C shows the two models superimposed onto the same image. For the results depicted in FIG. 21C the analytical results were solved alongside the FEA model. That is, using 250 N/m as the starting point, the distributed loads in the analytical model were iteratively increased until the curve matched the FEA model. The model shown in FIG. 21C uses 1700 N/m as the maximum point on the distributed load, and the corresponding point force is approximately 1.97 N. This point force remains over an order of magnitude lower than the force required to buckle the 200 μm diameter interconnection wire without accounting for the additional strength for the interconnection wires provided by the encapsulant. Accordingly, buckling of the first side or second interconnection wires is unlikely according to the model results depicted in FIGS. 21A-21C. From FIGS. 21A-21C, it can be tentatively concluded that the analytical and FEA models exhibit similar bending modes.

In both embodiments of analytical and FEA models including encapsulant as described above, the maximum stress was found to be at the interconnection wire and cross-connect wire joint. According to the results shown in FIGS. 21A-21C, the maximum computed stress reached about 530 MPa, which was approximately double the stress seen without an encapsulant (see FIGS. 16A-16C).

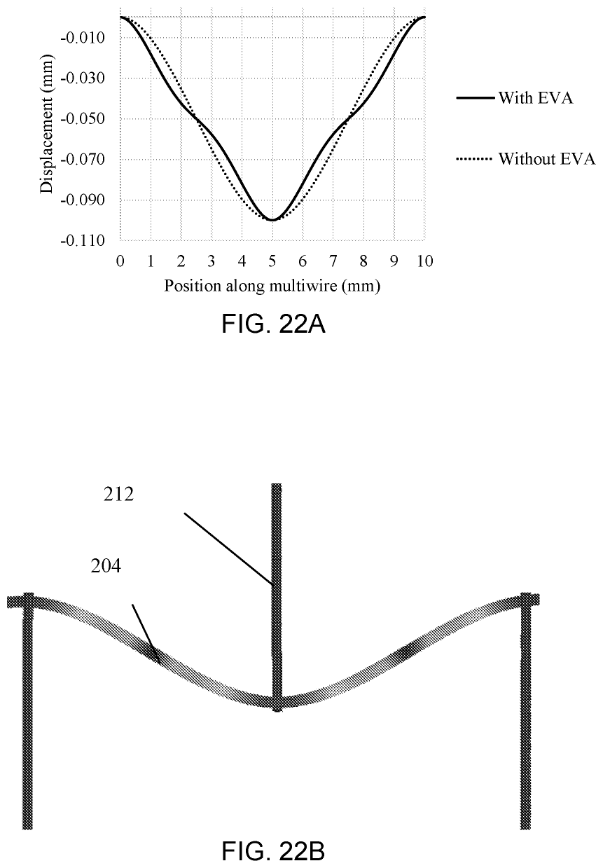

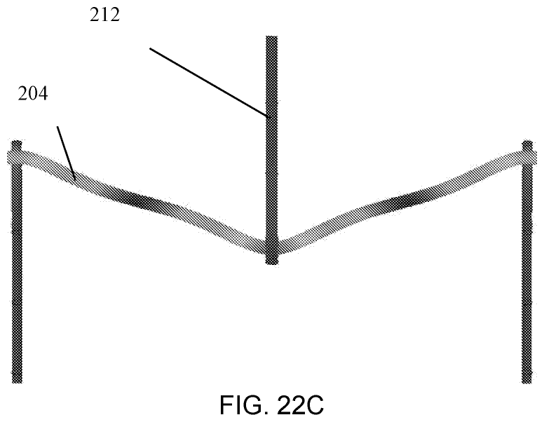

FIGS. 22A-22C depict a FEA comparison between the embodiments of a solar cell interconnection shown in FIGS. 15A-15B and FIGS. 19A-19B. As shown in FIG. 22A, the difference in bending modes with and without encapsulant is seen to be non-negligible. As discussed previously, the encapsulant applies a distributed load along the cross-connect wire, which can be seen to hold the cross-connect wire straight along unsupported lengths and deform it more directly adjacent to solder joints. According to the results shown in FIGS. 22A, these characteristics may be exhibited especially at 2.5 mm and around 5 mm, respectively.

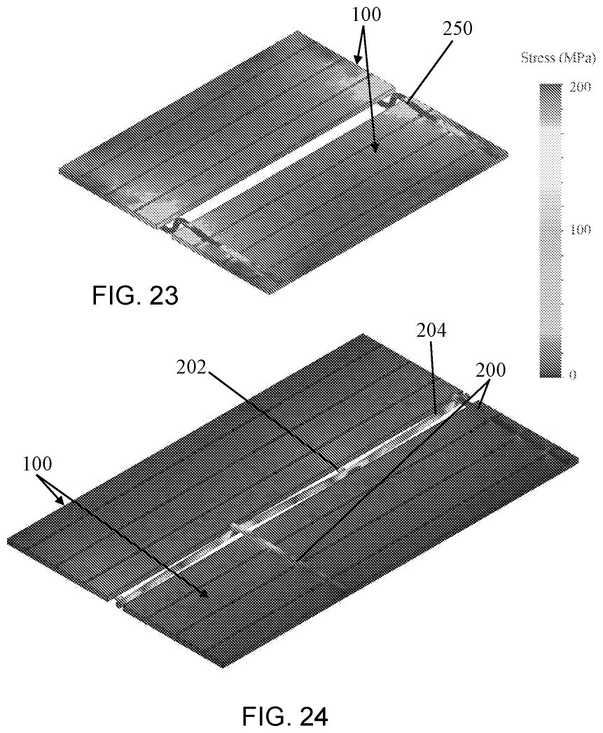

FIGS. 23- and 24 depict finite element analysis results for an encapsulated conventional interconnection and an encapsulated interconnection according to exemplary embodiments disclosed herein. The results shown in FIG. 24 confirm that stresses from displacements are redirected into the cross-connect wire 204 rather than the solar cell 100. For comparison, the results shown in FIG. 23 show that the encapsulated “S”-style interconnect 250 shows significant stresses into and out of the solar cell surface.

### Example: Displacement Cycle Testing

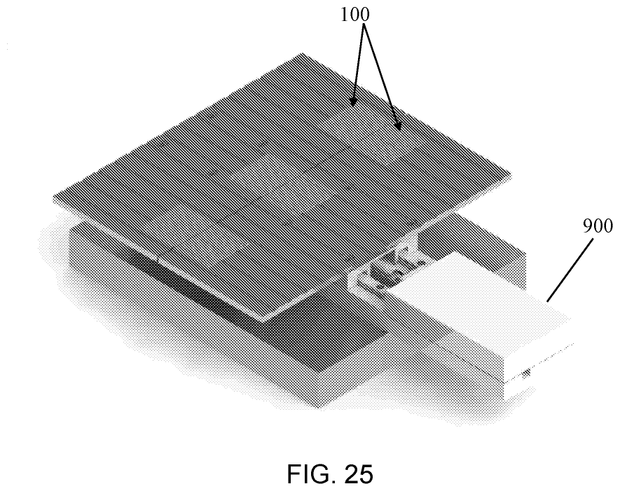

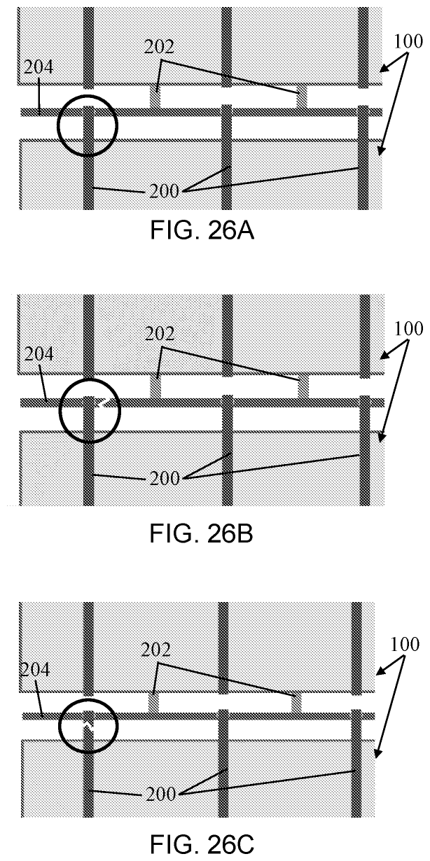

FIG. 25 depicts an embodiment for a testing assembly which may be used to test the models discussed above. According to this embodiment, a linear stage 900 with accuracy of less than one micron was built into a custom fatigue-testing tool. To mount a sample of two interconnected cells, two thin aluminum plates were used. One plate was stationary and one was mounted to the linear stage. Once the solar cells 100 were mounted to the plates, the stage was programmed to cycle ±100 μm, simulating the accelerated degradation seen in thermal cycling. For preliminary results, 200 μm thickness phosphorous bronze stock was used in place of silicon cell samples for ease of soldering and focusing stress on the interconnection first. For sunny side and back side interconnection wires, 250 μm diameter tinned copper wire was used. The cross-connect wire was tinned copper. This experiment helped in identifying failure modes at the interconnection, where some of the failure modes are shown in FIGS. 26A-26C.

FIGS. 26A-26C depict some possible failure modes of a solar cell interconnection. As shown in FIGS. 26A-26C, there are three primary failures. As shown in FIG. 26A, solder joint failures may occur when overstressed or at high counts of cyclic loading. As shown in FIG. 26B, cross-connect failures may also occur when thin cross-connect wires are used. As shown in FIG. 26C, interconnection wire failures may occur when thick cross-connect wires are used. However, it should be noted that failures occurred from atypical cyclic loading in a failure test environment. Therefore, it should be understood that any suitable thickness of interconnection wires and cross-connect wires may be used to form the interconnection, as the present disclosure is not so limited.

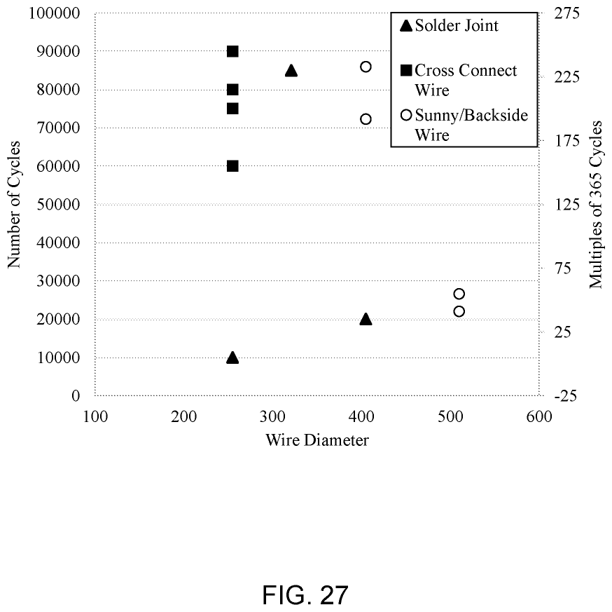

FIG. 27 depicts exemplary experimental failure testing data for embodiments of a solar cell interconnection. As shown in FIG. 27, the number of cycles at which the cell interconnection broke is plotted on the y-axis as a function of cross-connect wire diameter shown on the x-axis. Along the secondary y-axis, the cycles are given in terms of multiples of 365, which would roughly correspond to years of service life with the assumption there is one extreme thermal cycle per day and the system is not encapsulated. Without wishing to be bound by theory, the correlation between failure types and cross-connect wire diameter may be explained by deformation seen in the cross-connect wire during cycling. That is, the thinner a cross-connect wire is, the easier it is to bend and deform, which results in less tension and compression evident in the interconnection wires. Accordingly, the cross-connect wire experiences the greatest deformation in the system and is likely more susceptible to fatigue failures. In contrast, with thicker cross-connect wire diameters more force is necessary for the cross-connect wire to bend and deform. As all exemplary experiments use a ±100 μm displacement, increasing cross-connect diameter directly increases the force to displace the cells. Increased tension and compression in the sunny side and back side interconnection wires is therefore evident, explaining the failures in the interconnection wires at large cross-connect diameters. When there is a balance between stresses in the cross-connect and the interconnection wire such that neither experiences such extreme stresses or deformations, the solder joint may be the first location to break. Accordingly, in some embodiments a suitable cross-connect wire diameter may be slightly larger than the interconnection wire.

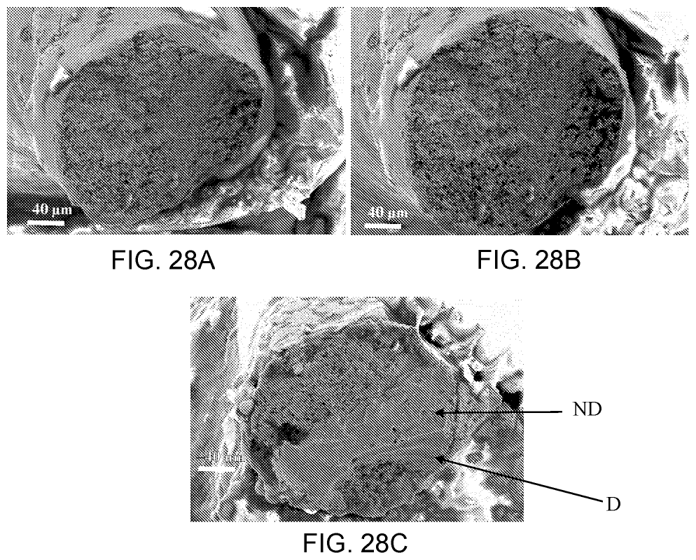

FIGS. 28A-28C depict microscopic views of failure modes of an embodiment of a solar cell interconnection. To determine the failure mode of the wire in the case of a cross-connect or interconnection wire break during an experiment, a scanning electron microscope (SEM) was used, the images from which are shown in FIGS. 28A-28C. In all of FIGS. 28A-28C, a small portion of the interconnection wire was broken along a 45° plane relative to the wire cross section. However, most of the failure surfaces were substantially flat and in the same plane as the wire cross section. Accordingly, a possible failure mode of the interconnection wire was that a crack in the wire is initiated through a more ductile mode. In such a failure mode, continued fatigue testing may lead to more of brittle break and ultimate wire failure. According to FIGS. 28A-28C, the surface textures of breaks in the cross-connect consistently appeared rougher and almost sponge-like compared with breaks in the interconnection wire. This surface implies that the cross-connect failure (see FIGS. 28A-28B) is consistently more ductile than the interconnection wire failure, which showed very flat areas (see FIG. 28C).

It should be understood that while particular modeling and physical experiments are described above where relatively high strains and stresses are developed in the interconnection and/or cross connect wires, these examples are meant to demonstrate that it is possible to move these strains and stresses from the connections between the interconnect wires and the surfaces of the solar cells to another location where it can be more easily managed. For example, bending and deformation of the cross-connect wires is described above. However, in addition to this benefit, it should be understood that the various interconnect and cross-connect wires may be appropriately constructed to handle the applied deformations and/or stresses. For example, the disclosed solar modules may include one or more of the following to address the applied stresses and/or deformations: the interconnect and/or cross connect wires may be formed from a conductive hardenable alloy such as a beryllium copper; the interconnect and/or cross connect wires may be formed from a soft annealed conductive material such as annealed copper to permit the wires to undergo plastic deformation when stressed; and/or a softer encapsulant may be used to help mitigate the developed stresses and strains. Of course it should also be understood that the presented examples and constructions are only exemplary and that a solar module may be appropriately designed to provide any desired combination of developed stresses and/or deformations for a desired application.

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art. Accordingly, the foregoing description and drawings are by way of example only.

1. A solar cell module, the module comprising:
a first solar cell and a second solar cell, wherein the first solar cell and the second solar cell both include an upper surface, a lower surface opposing the upper surface, at least one electrical contact located on the upper surface, and at least one electrical contact located on the lower surface;
at least one first interconnection wire that is disposed on and extends across at least a portion of the upper surface of the first solar cell, wherein the at least one first interconnection wire is in electrical contact with the at least one electrical contact on the upper surface of the first solar cell;
at least one second interconnection wire that is disposed on and extends across at least a portion of the lower surface of the second solar cell, wherein the at least one second interconnection wire is in electrical contact with the at least one electrical contact on the lower surface of the second solar cell; and
at least one cross-connect wire disposed between the first solar cell and the second solar cell, wherein the at least one cross-connect wire is in electrical contact with the at least one first interconnection wire and the at least one second interconnection wire.

2. The solar cell module of claim 1, wherein the at least one first interconnection wire is a plurality of first interconnection wires, and wherein the at least one second interconnection wire is a plurality of second interconnection wires.

3. The solar cell module of claim 2, wherein the plurality of first interconnection wires and the plurality of second interconnection wires are offset from one another in a direction perpendicular to a direction in which the plurality of first interconnection wires and the plurality of second interconnection wires extend.

4. The solar cell module of claim 3, wherein at least one of the plurality of first interconnection wires and at least one of the plurality of second interconnection wires are offset from one another by a distance that is between or equal to 2.5 to 7.5 mm.

5. The solar cell module of claim 3, wherein during thermal cycling of the first solar cell and the second solar cell the cross-connect wire bends to reduce stresses applied to the first and second solar cells.

6. The solar cell module of claim 1, wherein the at least one electrical contact on the upper surface of the first solar cell is at least one conductive finger.

7. The solar cell module of claim 6, wherein the at least one electrical contact on the lower surface of the second solar cell is a conductive sheet.

8. The solar cell module of claim 6, wherein the at least one electrical contact on the lower surface of the second solar cell is at least one metal strip.

9. The solar cell module of claim 6, wherein the first solar cell and the second solar cell are bifacial solar cells, and wherein the at least one electrical contact on the lower surface is at least one conductive finger.

10. The solar cell module of claim 1, wherein the at least one electrical contact on the upper surface is electrically isolated from the at least one electrical contact on the lower surface for each of the first solar cell and the second solar cell, and wherein the at least one electrical contact on the upper surface of the first solar cell is in electrical contact with the at least one electrical contact on the lower surface of the second solar cell.

11. The solar cell module of claim 1, wherein the at least one first interconnection wire also extends across at least a portion of the upper surface of the second solar cell and the at least one second interconnection wire also extends across at least a portion of the lower surface of the first solar cell, wherein each of the at least one first interconnection wires includes a cut out portion located between the cross-connect wire and the second solar cell, and wherein each of the at least one second interconnection wires includes a cut out portion located between the cross-connect wire and the first solar cell.

12. A method for interconnecting solar cells, the method comprising:
positioning a first solar cell proximate to a second solar cell, wherein the first solar cell and the second solar cell both include an upper surface, a lower surface opposing the upper surface, at least one electrical contact located on the upper surface, and at least one electrical contact located on the lower surface;
electrically connecting at least one first interconnection wire to the at least one electrical contact on the upper surface of both the first solar cell and second solar cell,
electrically connecting at least one second interconnection wire to the at least one electrical contact on the lower surface of both the first solar cell and second solar cell; and
electrically connecting a cross-connect wire to the at least one first interconnection wire and the at least one second interconnection wire, wherein the cross-connect wire is disposed between the first solar cell and the second solar cell.

13. The method of claim 12, wherein the step of positioning first solar cell proximate to the second solar cells occurs after electrically connecting the cross-connect wire to the at least one first interconnection wire and the at least one second interconnection wire.

14. The method of claim 12, wherein the at least one first interconnection wire is disposed on and extends across at least a portion of the upper surface of both the first solar cell and the second solar cell.

15. The method of claim 12, wherein the at least one second interconnection wire is disposed on and extends across at least a portion of the lower surface of both the first solar cell and the second solar cell.

16. The method of claim 12, further comprising removing a portion of the at least one first interconnection wire and removing a portion of the at least one second interconnection wire to electrically isolate the at least one electrical contact on the upper surface from the at least one electrical contact on the lower surface for each of the first solar cell and the second solar cell.

17. The method of claim 16, wherein the at least one electrical contact on the upper surface of the first solar cell is in electrical contact with the at least one electrical contact on the lower surface of the second solar cell.

18. The method of claim 12, further comprising cutting a portion of the at least one first interconnection wires at a position located between the cross-connect wire and the second solar cell, and cutting a portion of the at least one second interconnection wires at a position located between the cross-connect wire and the first solar cell.

19. The method of claim 12, wherein the at least one first interconnection wire is a plurality of first interconnection wires, and wherein the at least one second interconnection wire is a plurality of second interconnection wires.

20. The method of claim 19, wherein the plurality of first interconnection wires and the plurality of second interconnection wires are offset from one another in a direction perpendicular to a direction in which the plurality of first interconnection wires and the plurality of second interconnection wires extend.

21. The method of claim 20, wherein at least one of the plurality of first interconnection wires and at least one of the plurality of second interconnection wires are offset from one another by a distance that is between or equal to 2.5 to 7.5 mm.

22. The method of claim 20, further comprising bending the cross-connect wire to reduce stresses applied to the first and second solar cells during thermal cycling of the first solar cell.

23. The solar cell module of claim 12, wherein each of the at least one electrical contact on the upper surface of both the first solar cell and the second solar cell is at least one conductive finger.

24. The solar cell module of claim 23, wherein each of the at least one electrical contact on the lower surface of both the first solar cell and the second solar cell is a conductive sheet.

25. The solar cell module of claim 23, wherein each of the at least one electrical contact on the lower surface of both the first solar cell and the second solar cell is at least one metal strip.

26. The solar cell module of claim 23, wherein each of the first solar cell and the second solar cell is a bifacial solar cell, and wherein each of the at least one electrical contact on the lower surface of both the first solar cell and the second solar cell is at least one conductive finger.

27. A solar cell module, the module comprising:
a first solar cell and a second solar cell, wherein the first solar cell and the second solar cell both include an upper surface, a lower surface opposing the upper surface, at least one electrical contact located on the upper surface, and at least one electrical contact located on the lower surface;
at least one first interconnection wire that is disposed on and extends across at least a portion of the upper surface of both the first solar cell and the second solar cell, wherein the at least one first interconnection wire is in electrical contact with the at least one electrical contact on the upper surface of both the first solar cell and the second solar cell;
at least one second interconnection wire that is disposed on and extends across at least a portion of the lower surface of both the first solar cell and the second solar cell, wherein the at least one second interconnection wire is in electrical contact with the at least one electrical contact on the lower surface of both the first solar cell and the second solar cell; and
at least one cross-connect wire disposed between the first solar cell and the second solar cell, wherein the at least one cross-connect wire is in electrical contact with the at least one first interconnection wire and the at least one second interconnection wire.

28. The solar cell module of claim 27, wherein the at least one first interconnection wire is a plurality of first interconnection wires, and wherein the at least one second interconnection wire is a plurality of second interconnection wires.

29. The solar cell module of claim 28, wherein the plurality of first interconnection wires and the plurality of second interconnection wires are offset from one another in a direction perpendicular to a direction in which the plurality of first interconnection wires and the plurality of second interconnection wires extend.

30. The solar cell module of claim 29, wherein at least one of the plurality of first interconnection wires and at least one of the plurality of second interconnection wires are offset from one another by a distance that is between or equal to 2.5 to 7.5 mm.

31. The solar cell module of claim 29, wherein during thermal cycling of the first solar cell and the second solar cell the cross-connect wire bends to reduce stresses applied to the first and second solar cells.

32. The solar cell module of claim 27, wherein each of the at least one electrical contact on the upper surface of both the first solar cell and the second solar cell is as at least one conductive finger.

33. The solar cell module of claim 32, wherein each of the at least one electrical contact on the lower surface of both the first solar cell and the second solar cell is a conductive sheet.

34. The solar cell module of claim 32, wherein each of the at least one electrical contact on the lower surface of both the first solar cell and the second solar cell is at least one metal strip.

35. The solar cell module of claim 32, wherein each of the first solar cell and the second solar cell is a bifacial solar cell, and wherein each of the at least one electrical contact on the lower surface of both the first solar cell and the second solar cell is at least one conductive finger.

36-55. (canceled)
